(19) United States
(12) Patent Application Publication
(10) Pub. No.: US 2025/0081845 A1
(43) Pub. Date: Mar. 6, 2025

(54) QUANTUM DOT LIGHT-EMITTING DEVICE AND PREPARATION METHOD THEREFOR, AND DISPLAY APPARATUS

(71) Applicants: Beijing BOE Technology Development Co., Ltd., Beijing (CN); BOE Technology Group Co., Ltd., Beijing (CN)

(72) Inventor: Dong LI, Beijing (CN)

(21) Appl. No.: 18/580,630

(22) PCT Filed: Aug. 4, 2022
(86) PCT No.: PCT/CN2022/110301

§ 371 Date: Jan. 19, 2024

(30) Foreign Application Priority Data
Aug. 11, 2021 (CN) 202110919258.1

(51) Int. Cl. H10K 85/60; H10K 50/115; H10K 50/16; H10K 101/40

(52) U.S. Cl. CPC H10K 85/657; H10K 85/60; H10K 85/633; H10K 85/636; H10K 50/115; H10K 50/16; H10K 85/615; H10K 85/6572; H10K 2101/40

(57) ABSTRACT

A quantum dot light-emitting device and a preparation method therefor, and a display apparatus. The quantum dot light-emitting device comprises: a quantum dot light-emitting layer; a carrier transport layer, which is located on at least one side of the quantum dot light-emitting layer; and a monomolecular layer, which is located between the carrier transport layer and the quantum dot light-emitting layer, wherein the material of the monomolecular layer is configured in such a way that a molecular configuration thereof is converted from a cis-configuration to a trans-configuration under a visible light irradiation condition or a heating condition, and the molecular configuration thereof is converted from the trans-configuration to the cis-configuration under an ultraviolet irradiation condition, and the molecular chain length of the trans-configuration is greater than the molecular chain length of the cis-configuration.

### CROSS-REFERENCE TO RELATED APPLICATIONS

The present application is a U.S. National Phase Entry of International Application No. PCT/CN2022/110301, having an international filing date of Aug. 4, 2022, which claims priority of Chinese Patent Application No. 202110919258.1 filed to the CNIPA on Aug. 11, 2021 and titled “Quantum Dot Light-emitting Device and Preparation Method Therefor, and Display Apparatus”. The entire contents of the above-identified applications are incorporated herein by reference.

### TECHNICAL FIELD

Embodiments of the present disclosure relate to, but are not limited to, the field of display technologies, in particular to a quantum dot light-emitting device and a preparation method therefor, and a display apparatus including the quantum dot light-emitting device.

### BACKGROUND

As a new luminescent material, Quantum Dots (QD) have the advantages of high light color purity, high luminous quantum efficiency, adjustable color of emitted light, long service life, etc., and have become a hot spot in the current research of new Light-Emitting Diode (LED) luminescent materials. Therefore, Quantum Dot Light Emitting Diodes (QLED) in which a quantum dot material is used as a light-emitting layer have become a main direction of the current research on new display devices.

Due to the characteristics of quantum dot materials, a printing technology or printing method is generally used, which may effectively improve the utilization rate of materials and is an effective way to prepare quantum dot film layers in large areas. At the time of preparing a quantum dot film layer by an inkjet printing process, before depositing each film layer of an electroluminescent (EL) unit, a pixel definition layer will be prepared in advance. Ink of each functional layer will have a problem of climbing on the bank, even climbing to a top platform area of the bank, which greatly affects the morphology of quantum dot film layers and uniformity of thickness of the film layers, and will greatly affect device performance and uniformity, thus affecting the mass production of QLEDs. This problem is especially significant on high-resolution substrates. If the film layers before the quantum dot layer, such as Hole Injection Layer (HIL) and Hole Transport Layer (HTL), are also prepared by wet process, they will also have the problem of non-uniformity of the film layers, and the non-uniformity of each layer accumulates layer by layer, which further affects the uniformity of the quantum dot light-emitting layer and the final EL unit.

In order to solve the problem of non-uniformity of thickness of the film layers in mass production, an inorganic electron transport layer may be used before the quantum dot light-emitting layer, and a flat thin film may be formed by a process such as sputtering. However, whether an inorganic electron transport layer or an organic electron transport layer is used, due to the large mobility of Electron Transport (ET) materials, electron injection in devices is excessive, which results in enrichment of a large number of electrons, affecting carrier balance. Moreover, Auger recombination in QD leads to a reduction in quantum efficiency (QY), which ultimately affects the luminous efficiency of devices. In another aspect, there are many defects on a surface of an inorganic oxide electron transport layer, which has a quenching effect on QDs, and will also affect the luminous efficiency of devices.

### SUMMARY

The following is a summary of subject matter described herein in detail. The summary is not intended to limit the protection scope of the present application.

An embodiment of the present disclosure provides a quantum dot light-emitting device, including:
a quantum dot light-emitting layer;
a carrier transport layer, located on at least one side of the quantum dot light-emitting layer; and
a monomolecular layer, located between the carrier transport layer and the quantum dot light-emitting layer;
wherein a material of the monomolecular layer is configured in such a way that a molecular configuration is converted from a cis-configuration to a trans-configuration under a visible light irradiation condition or a heating condition, and the molecular configuration is converted from the trans-configuration to the cis-configuration under an ultraviolet irradiation condition, and a molecular chain length of the trans-configuration is greater than that of the cis-configuration.

In an exemplary embodiment, the monomolecular layer may be a self-assembled monomolecular layer.

In an exemplary embodiment, the material of the monomolecular layer may contain at least one of an azo group and

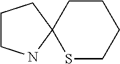

group.

In an exemplary embodiment, a general structural formula of the material of the monomolecular layer may be:

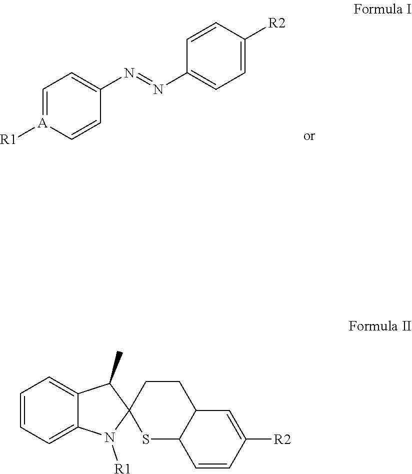

wherein, A in Formula I is a carbon atom or an ammonium ion, and when A in Formula I is an ammonium ion, Formula I further includes a halogen anion which is selected from at least one of F⁻, Cl⁻, Br⁻ and I⁻; and R1 and R2 in Formula I and Formula II are each independently selected from at least one of alkyl group, —NH₂, amine group, alcoholamine group, —NO₂, —COOH, and a group containing a carbon-carbon double bond.

In an exemplary embodiment, the material of the monomolecular layer may be selected from any one or more of the following compounds:

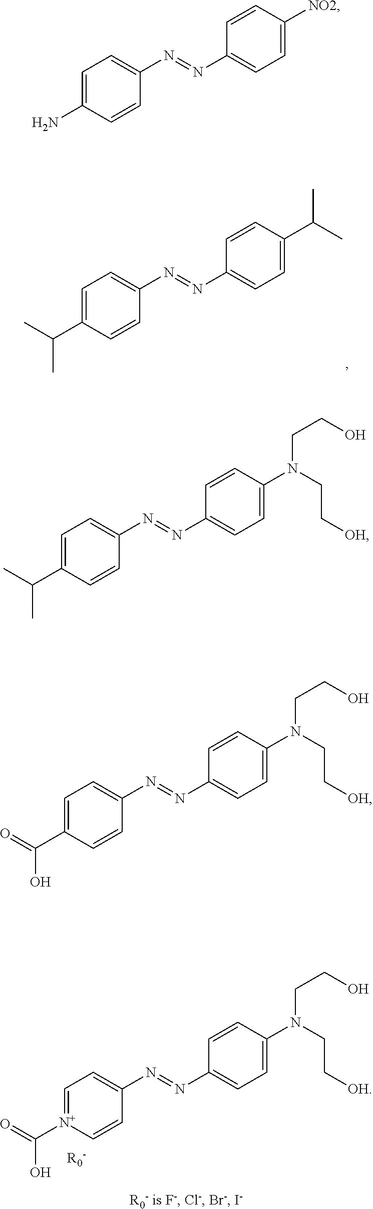

In an exemplary embodiment, the material of the monomolecular layer may be a ligand that is coordinately bound to a quantum dot of the quantum dot light-emitting layer.

In an exemplary embodiment, the ligand may contain at least one of an azo group and

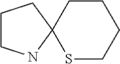

group.

In an exemplary embodiment, a general structural formula of the ligand may be:

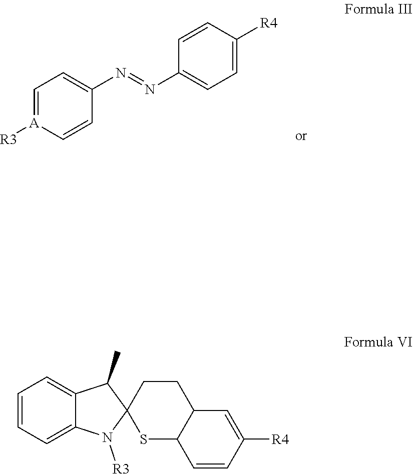

wherein, A in Formula III is a carbon atom or an ammonium ion, and when A in Formula III is an ammonium ion, Formula III further includes a halogen anion which is selected from at least one of F⁻, Cl⁻, Br⁻ and I⁻; in Formula III and Formula VI, one of R3 and R4 contains a coordination group capable of being coordinately bound to the quantum dot, and the other one of R3 and R4 is a free end, and the coordination group is selected from any one or more of mercapto group, hydroxyl group, amine group, amino group, carboxyl group, ester group, phosphine group and phosphoroxy group.

In an exemplary embodiment, the ligand may be selected from any one or more of.

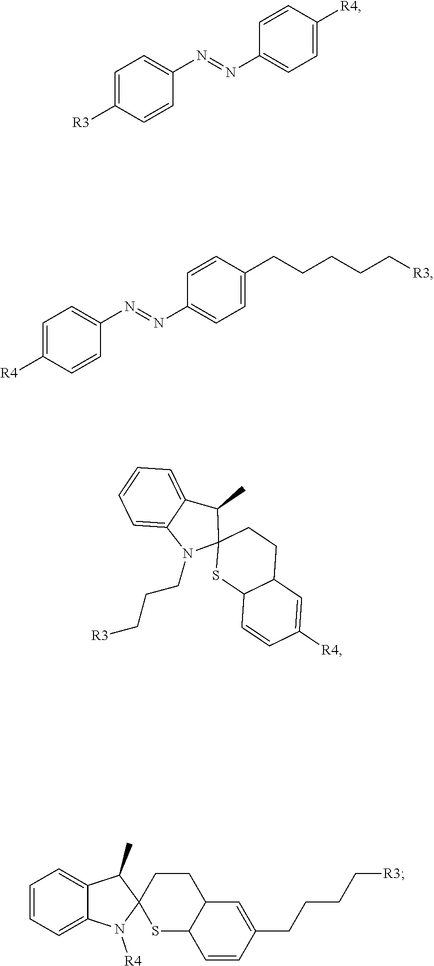

wherein R3 is the coordination group, and R4 is a free end.

In an exemplary embodiment, the free end may contain a siloxane group.

In an exemplary embodiment, the material of the monomolecular layer may be configured such that the molecular configuration is converted from a cis-configuration to a trans-configuration under an 80° C.-150° C. heating condition.

In an exemplary embodiment, the carrier transport layer may be an electron transport layer and includes an inorganic metal oxide nanoparticle thin film or an inorganic metal oxide thin film, wherein the inorganic metal oxide may be selected from any one or more of ZnO, TiO₂, SnO₂, and ZrO₂;
wherein ZnO may include metal-doped ZnO, and metal doped in the metal-doped ZnO may be selected from any one or more of Mg, Al, Zr, and Y.

In an exemplary embodiment, the electron transport layer may include a red sub-pixel electron transport layer, a green sub-pixel electron transport layer, and a blue sub-pixel electron transport layer;
the red sub-pixel electron transport layer is an inorganic metal oxide nanoparticle thin film or an inorganic metal oxide thin film, wherein the inorganic metal oxide may be ZnO or ZnMgO;
the green sub-pixel electron transport layer is an inorganic metal oxide nanoparticle thin film or an inorganic metal oxide thin film, wherein the inorganic metal oxide may be ZnO or ZnMgO;
the blue sub-pixel electron transport layer is an inorganic metal oxide nanoparticle thin film or an inorganic metal oxide thin film, wherein the inorganic metal oxide may be ZnO or ZnMgO.

In an exemplary embodiment, the red sub-pixel electron transport layer, the green sub-pixel electron transport layer, and the blue sub-pixel electron transport layer may be a ZnMgO nanoparticle thin film or a ZnMgO thin film, a weight percent content of Mg in ZnMgO of the red sub-pixel electron transport layer is less than a weight percent content of Mg in ZnMgO of the green sub-pixel electron transport layer, and the weight percent content of Mg in ZnMgO of the green sub-pixel electron transport layer is less than a weight percent content of Mg in ZnMgO of the blue sub-pixel electron transport layer.

In an exemplary embodiment, the carrier transport layer is a hole transport layer, and a material of the hole transport layer may be selected from any one or more of an organic hole transport material and an inorganic metal oxide hole transport material;
the organic hole transport material may include any one or more of poly(9,9-dioctylfluorene-CO—N-(4-butylphenyl)diphenylamine) (TFB), polyvinylcarbazole (PVK), N,N′-bis(3-methylphenyl)-N,N′-diphenyl-1,1′-biphenyl-4,4′-diamine (TPD), and 4,4′-bis(9-carbazolyl)biphenyl (CBP);
the inorganic metal oxide hole transport material may include any one or more of NiO, NiO₂, and V₂O₅.

In an exemplary embodiment, the hole transport layer may include a first hole transport layer close to the quantum dot light-emitting layer and a second hole transport layer away from the quantum dot light-emitting layer, a material of the first hole transport layer is a first hole transport material, and a material of the second hole transport layer is a second hole transport material;

$$- 6.2 eV ⩽ \vert HOMO ( A ) \vert ⩽ - 5.5 eV ; - 5.5 eV ⩽ \vert HOMO ( B ) \vert ⩽ - 5. eV$$

wherein HOMO (A) is the highest occupied molecular orbital HOMO energy level of the first hole transport material, and HOMO (B) is the highest occupied molecular orbital HOMO energy level of the second hole transport material.

In an exemplary embodiment, the carrier transport layer may be located on both sides of the quantum dot light-emitting layer, the carrier transport layer on one side of the quantum dot light-emitting layer is an electron transport layer, and the carrier transport layer on the other side of the quantum dot light-emitting layer is a hole transport layer;
the electron transport layer may include an inorganic metal oxide nanoparticle thin film or an inorganic metal oxide thin film, wherein the inorganic metal oxide may be selected from any one or more of ZnO, TiO₂, SnO₂, and ZrO₂; wherein ZnO may include metal-doped ZnO, and metal doped in the metal-doped ZnO may be selected from any one or more of Mg, Al, Zr, and Y;
the material of the hole transport layer may be selected from any one or more of an organic hole transport material and an inorganic metal oxide hole transport material; wherein the organic hole transport material may include any one or more of poly(9,9-dioctylfluorene-CO—N-(4-butylphenyl)diphenylamine), polyvinylcarbazole, N,N′-bis(3-methylphenyl)-N,N′-diphenyl-1,1′-biphenyl-4,4′-diamine, and 4,4′-bis(9-carbazolyl)biphenyl; and the inorganic metal oxide hole transport material may include any one or more of NiO, NiO₂, and V₂O₅.

In an exemplary embodiment, the electron transport layer may include a red sub-pixel electron transport layer, a green sub-pixel electron transport layer, and a blue sub-pixel electron transport layer;
the red sub-pixel electron transport layer is an inorganic metal oxide nanoparticle thin film or an inorganic metal oxide thin film, wherein the inorganic metal oxide may be ZnO or ZnMgO;
the green sub-pixel electron transport layer is an inorganic metal oxide nanoparticle thin film or an inorganic metal oxide thin film, wherein the inorganic metal oxide may be ZnO or ZnMgO;
the blue sub-pixel electron transport layer is an inorganic metal oxide nanoparticle thin film or an inorganic metal oxide thin film, wherein the inorganic metal oxide may be ZnO or ZnMgO.

In an exemplary embodiment, the red sub-pixel electron transport layer, the green sub-pixel electron transport layer, and the blue sub-pixel electron transport layer may be a ZnMgO nanoparticle thin film or a ZnMgO thin film, a weight percent content of Mg in ZnMgO of the red sub-pixel electron transport layer is less than a weight percent content of Mg in ZnMgO of the green sub-pixel electron transport layer, and the weight percent content of Mg in ZnMgO of the green sub-pixel electron transport layer is less than a weight percent content of Mg in ZnMgO of the blue sub-pixel electron transport layer.

In an exemplary embodiment, the hole transport layer may include a first hole transport layer close to the quantum dot light-emitting layer and a second hole transport layer away from the quantum dot light-emitting layer, a material of the first hole transport layer is a first hole transport material, and a material of the second hole transport layer is a second hole transport material;

$$- 6.2 eV ⩽ \vert HOMO ( A ) \vert ⩽ - 5.5 eV ; - 5.5 eV ⩽ \vert HOMO ( B ) \vert ⩽ - 5. eV$$

wherein HOMO (A) is the highest occupied molecular orbital HOMO energy level of the first hole transport material, and HOMO (B) is the highest occupied molecular orbital HOMO energy level of the second hole transport material.

In an exemplary embodiment, the first hole transport material may be selected from any one or both of 4,4′,4″-tris(carbazol-9-yl)triphenylamine) (TCTA) and 4,4′-cyclohexylbis[N,N-bis(4-methylphenyl)aniline](TAPC), and the second hole transport material may be selected from any one or both of 4,4′-bis[N-(1-naphthyl)-N-phenylamino]biphenyl (NPB) and 4,4′,4″-tris(N-3-methylphenyl-N-phenylamino)triphenylamine (m-MTDATA).

In an exemplary embodiment, a thickness of the hole transport layer may be 20 nm to 60 nm, a thickness of the first hole transport layer may be T_{A}, 0 nm<T_{A}≤10 nm, and a thickness of the second hole transport layer may be T_{B}, 20 nm≤T_{B}≤60 nm.

An embodiment of the present disclosure further provides a preparation method for the quantum dot light-emitting device described above, including:
forming a quantum dot light-emitting layer;
forming a carrier transport layer; and
forming a monomolecular layer between the carrier transport layer and the quantum dot light-emitting layer.

In an exemplary embodiment, the monomolecular layer is a self-assembled monomolecular layer, and the forming the monomolecular layer may include:
dissolving a material of the monomolecular layer in a solvent to form a solution containing the material of the monomolecular layer; and
forming the monomolecular layer from the solution containing the material of the monomolecular layer by means of film formation by soaking or spin coating.

In an exemplary embodiment, a temperature for the film formation by soaking may be room temperature, soaking time of the film formation by soaking may be 20 min to 50 min, and the solvent for dissolving the material of the monomolecular layer may be selected from any one or more of ethanol, ether, acetic acid, alkane, N,N-dimethylformamide (DMF), and dimethyl sulfoxide (DMSO).

In an exemplary embodiment, the material of the monomolecular layer is a ligand, and the preparation method may include:
providing an initial quantum dot containing an oil-soluble ligand;
performing ligand exchange by using the ligand with the oil-soluble ligand on a surface of the initial quantum dot to obtain a quantum dot containing a ligand; and
forming the quantum dot light-emitting layer and the monomolecular layer by using the quantum dot containing the ligand.

In an exemplary embodiment, the performing ligand exchange by using the ligand with the oil-soluble ligand on a surface of the initial quantum dot to obtain a quantum dot containing a ligand may include:
dissolving the ligand in an organic solvent to obtain a ligand solution;
adding the initial quantum dot into the ligand solution to obtain a ligand solution containing the initial quantum dot, stirring, and performing ligand exchange by using the ligand with the oil-soluble ligand on the surface of the initial quantum dot; and
adding the solution obtained after the ligand exchange into an undesirable solvent of the ligand so that the quantum dot containing the ligand is precipitated and separated from the solution.

In an exemplary embodiment, the organic solvent may be selected from any one or more of alcohol solvents, and the undesirable solvent of the ligand may be water.

An embodiment of the present disclosure further provides a display apparatus, including a plurality of quantum dot light-emitting devices described above.

After the drawings and the detailed descriptions are read and understood, the other aspects may be comprehended.

### BRIEF DESCRIPTION OF DRAWINGS

The accompany drawings are used to provide further understanding of the technical solution of the present disclosure, and form a part of the description. The accompany drawings and embodiments of the present disclosure are adopted to explain the technical solution of the present disclosure, and do not form limits to the technical solution of the present disclosure.

FIG. 1 is a schematic diagram of an isomerization reaction of a material of a monomolecular layer of a quantum dot light-emitting device according to an exemplary embodiment of the present disclosure.

FIG. 2 shows capacitance changes of an interface between an electron transport layer and a quantum dot light-emitting layer in a quantum dot light-emitting device, before and after a change in a molecular configuration of a material of a monomolecular layer of the quantum dot light-emitting device under a light irradiation condition according to an exemplary embodiment of the present disclosure.

FIG. 3 is a diagram of changes of molecular configuration conversion of a material of a monomolecular layer of a quantum dot light-emitting device in an inverted structure and current of the quantum dot light-emitting device with a gate voltage under different light irradiation conditions according to an exemplary embodiment of the present disclosure.

FIG. 4 is a schematic diagram of a change of a molecular configuration of a material of a monomolecular layer shown in Formula II.

FIG. 5 is a schematic structural diagram of a QLED device in an inverted structure according to an exemplary embodiment of the present disclosure.

FIG. 6 is a schematic structural diagram of a QLED device in an inverted structure according to another exemplary embodiment of the present disclosure.

FIG. 7 is a schematic structural diagram of a QLED device in an inverted structure according to a further exemplary embodiment of the present disclosure.

FIG. 8 is a schematic diagram of an arrangement of an electron transport layer of the QLED device in an inverted structure shown in FIG. 5.

FIG. 9 is a schematic diagram of an arrangement of a hole transport layer of the QLED device in an inverted structure shown in FIG. 5.

FIG. 10 is a schematic structural diagram of a QLED device in an upright structure according to an exemplary embodiment of the present disclosure.

FIG. 11 is a schematic structural diagram of a QLED device in an upright structure according to another exemplary embodiment of the present disclosure.

FIG. 12 is a schematic structural diagram of a QLED device in an upright structure according to a further exemplary embodiment of the present disclosure.

Meanings of reference signs in the accompanying drawings are as follows:

100—anode; 200—hole injection layer; 300—hole transport layer; 301—first hole transport layer; 302—second hole transport layer; 400—quantum dot light-emitting layer; 500—monomolecular layer; 501—first monomolecular layer; 502—second monomolecular layer; 600—electron transport layer; 601—red sub-pixel electron transport layer; 602—green sub-pixel electron transport layer; 603—blue sub-pixel electron transport layer; and 700—cathode.

### DETAILED DESCRIPTION

Implementations herein may be implemented in multiple different forms. Those of ordinary skills in the art can readily appreciate a fact that the implementations and contents may be varied into various forms without departing from the spirit and scope of the present disclosure. Therefore, the present disclosure should not be explained as being limited to the contents recorded in the following implementations only. The embodiments and features in the embodiments of the present disclosure may be randomly combined with each other in case of no conflicts.

In the accompanying drawings, a size of a constituent element, and a thickness of a layer or a region is sometimes exaggerated for clarity. Therefore, any one embodiment of the present disclosure is not necessarily limited to dimensions shown in the drawings, and the shapes and sizes of the components in the accompanying drawings do not reflect actual scales. In addition, the accompanying drawings schematically show an ideal example, and any one embodiment of the present disclosure is not limited to the shapes, values, or the like shown in the accompanying drawings.

Ordinal numerals “first”, “second”, etc., in the specification are set not to form limits in number but only to avoid the confusion of composition elements.

In the specification, a “film” and a “layer” are interchangeable. For example, “quantum dot film” can sometimes be replaced by “quantum dot layer”.

An embodiment of the present disclosure provides a quantum dot light-emitting device, including:
a quantum dot light-emitting layer;
a carrier transport layer, located on at least one side of the quantum dot light-emitting layer; and
a monomolecular layer, located between the carrier transport layer and the quantum dot light-emitting layer;
wherein a material of the monomolecular layer is configured in such a way that a molecular configuration is converted from a cis-configuration to a trans-configuration under a visible light irradiation condition or a heating condition, and the molecular configuration is converted from the trans-configuration to the cis-configuration under an ultraviolet irradiation condition, and a molecular chain length of the trans-configuration is greater than that of the cis-configuration.

In the quantum dot light-emitting device according to an embodiment of the present disclosure, a monomolecular layer is introduced, the material of the monomolecular layer undergoes an isomerization reaction under a visible light irradiation condition or a heating condition, the molecular configuration of the material of the monomolecular layer obtained after the isomerization reaction is converted from a cis-configuration to a trans-configuration, the conjugation state of molecules in the layer changes, and the molecular chain length changes, so a distance between the carrier transport layer and the quantum dot light-emitting layer may be adjusted.

The quantum dot light-emitting device according to an embodiment of the present disclosure can emit visible light when working and generate heat at the same time, which induces an isomerization reaction of the material of the monomolecular layer to form a trans-configuration, and increases the chain length, so that the spacing between the carrier transport layer and the quantum dot light-emitting layer becomes larger, thereby achieving the effects of weakening electron injection and reducing quenching of quantum dots, and improving the light-emitting efficiency.

In an exemplary embodiment, the monomolecular layer may be a self-assembled monomolecular layer.

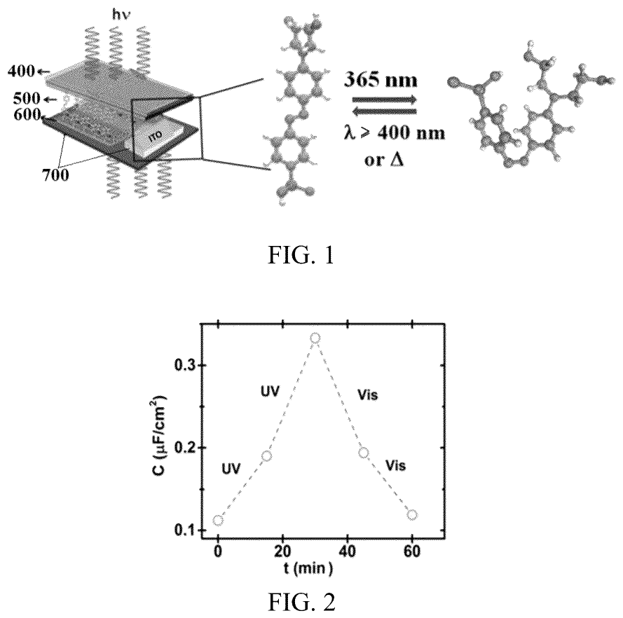

FIG. 1 is a schematic diagram of an isomerization reaction of a material of a monomolecular layer of a quantum dot light-emitting device according to an exemplary embodiment of the present disclosure. As shown in FIG. 1, under the irradiation of visible light, for example, with a wavelength of λ≥400 nm, or under a heating condition, the molecular configuration of the material of the monomolecular layer is converted from a cis-configuration to a trans-configuration. Since the molecular chain length of the trans-configuration is larger than that of the cis-configuration, the conversion of the molecular configuration enables the spacing between the carrier transport layer and the quantum dot light-emitting layer to become larger, thus achieving the effect of weakening electron injection and also inhibiting quenching of QDs due to surface defects of the carrier transport layer of an inorganic metal oxide material. Under the irradiation of ultraviolet light, for example, with a wavelength of 365 nm, the molecular configuration of the material of the self-assembled monomolecular layer is further converted from a trans-configuration to a cis-configuration, and the molecular chain length becomes smaller.

FIG. 2 shows capacitance changes of an interface between an electron transport layer and a quantum dot light-emitting layer in a quantum dot light-emitting device, before and after a change in a molecular configuration of a material of a monomolecular layer of the quantum dot light-emitting device under a light irradiation condition according to an exemplary embodiment of the present disclosure. As can be seen, after the molecular configuration of the material of the monomolecular layer is converted into a cis-configuration under the irradiation of ultraviolet light (UV, herein, referring to light with a wavelength of 10 nm to 400 nm), the interface capacitance becomes larger and the ability to transport electrons becomes stronger; but under the irradiation of visible light (Vis, herein, referring to light with a wavelength in the range of 400 nm to 700 nm), the interface capacitance becomes smaller and the ability to transport electrons becomes poor.

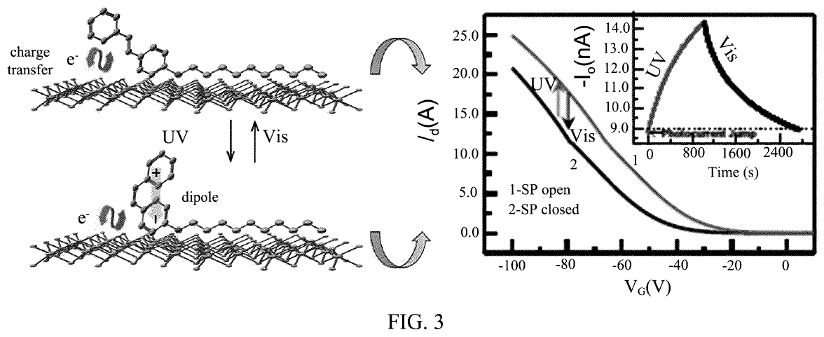

FIG. 3 is a diagram of changes of molecular configuration conversion of a material of a monomolecular layer of a quantum dot light-emitting device in an inverted structure and current (I_{d}) of the quantum dot light-emitting device with a gate voltage (V_{G}) under different light irradiation conditions according to an exemplary embodiment of the present disclosure. Here, configuration change of the monomolecular layer is characterized by a channel current test of the quantum dot light-emitting device. The characterization principle is that the molecular configuration of the material of the monomolecular layer changes under different irradiation conditions, which leads to a change in the distance between an active layer and a gate insulating layer in the quantum dot light-emitting device in an inverted structure, resulting in a change in channel current. As can be seen, when the molecular configuration of the material of the monomolecular layer is a cis-configuration, dipoles are formed in the molecules, and the degree of conjugation between the upper and lower molecules is enhanced, which increases the current of the quantum dot light-emitting device.

In an exemplary embodiment, the material of the monomolecular layer may contain at least one of an azo group and

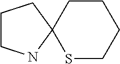

group.

In an exemplary embodiment, a general structural formula of the material of the monomolecular layer may be:

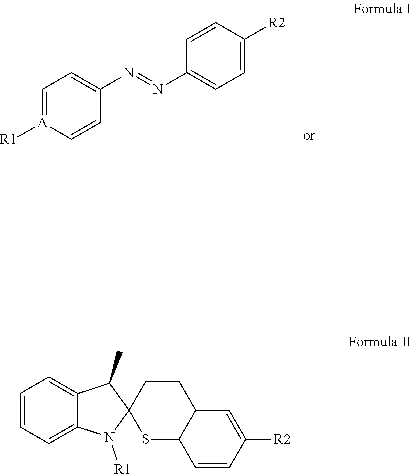

wherein, A in Formula I is a carbon atom or an ammonium ion, and when A in Formula I is an ammonium ion, Formula I further includes a halogen anion which is selected from at least one of F⁻, Cl⁻, Br⁻ and I⁻; R1 and R2 in Formula I and Formula II are each independently selected from at least one of alkyl group, —NH₂, amine group (e.g., monoalkylamine group, dialkylamine group), alcoholamine group (e.g., —N(C₂H₄OH)₂, —N(CH₂OH)₂, —NHC₂H₄OH), —NO₂, —COOH, and a group containing a carbon-carbon double bond (e.g., —CH═CH₂), herein, there is no requirement for a carbon chain length of alkyl group, for example, the carbon chain length of alkyl group may be 4 to 8.

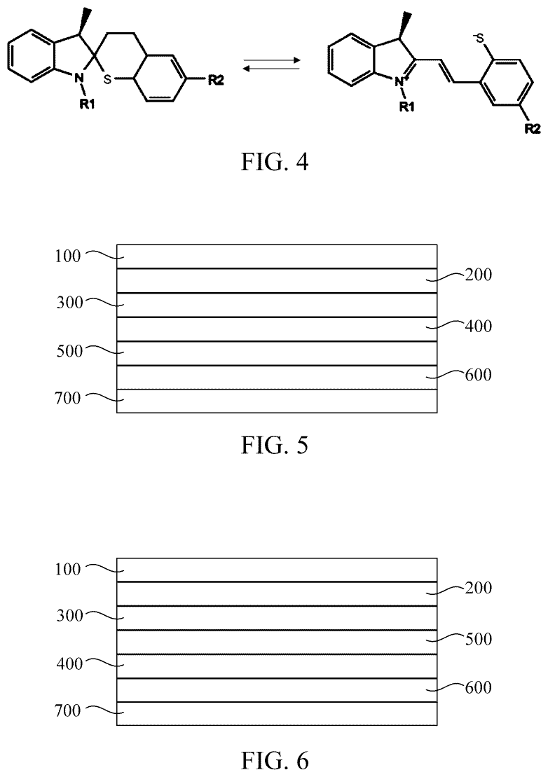

FIG. 4 is a schematic diagram of a change of a molecular configuration of a material of a monomolecular layer shown in Formula II.

In an exemplary embodiment, the material of the monomolecular layer may be selected from any one or more of the following compounds:

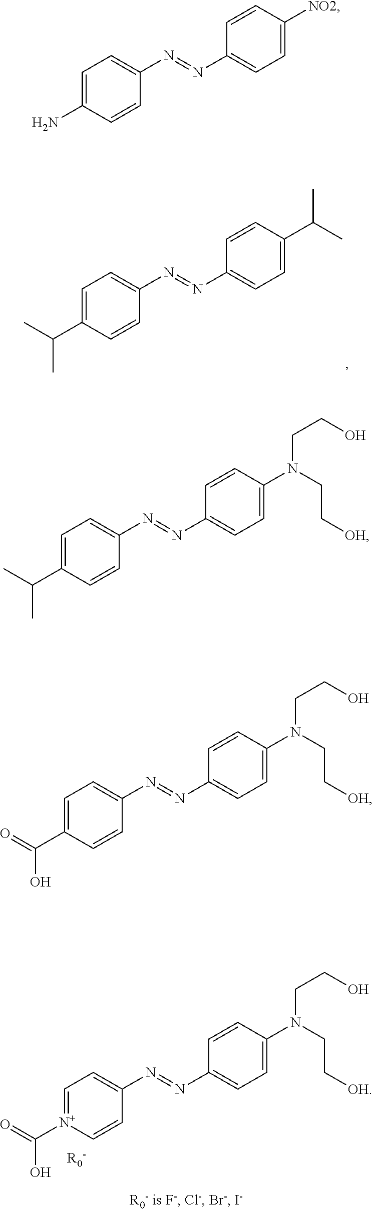

In an exemplary embodiment, the material of the monomolecular layer may be a ligand that is coordinately bound to a quantum dot of the quantum dot light-emitting layer.

In an exemplary embodiment, the ligand may contain at least one of an azo group and

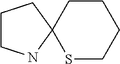

group.

In an exemplary embodiment, a general structural formula of the ligand may be:

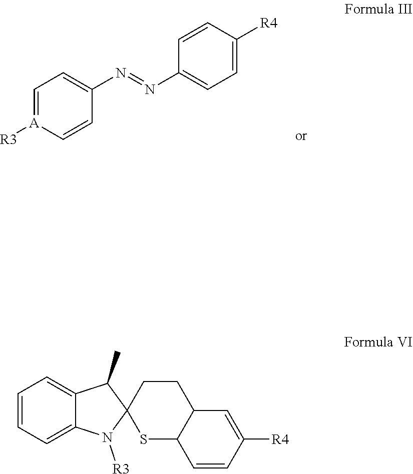

wherein, A in Formula III is a carbon atom or an ammonium ion, and when A in Formula III is an ammonium ion, Formula III further includes a halogen anion which is selected from at least one of F⁻, Cl⁻, Br⁻ and I⁻; in Formula III and Formula VI, one of R3 and R4 contains a coordination group capable of being coordinately bound to the quantum dot, and the other one of R3 and R4 is a free end, and the coordination group is selected from any one or more of mercapto group, hydroxyl group, amine group, amino group, carboxyl group, ester group, phosphine group and phosphoroxy group.

In an exemplary embodiment, the ligand may be selected from any one or more of:

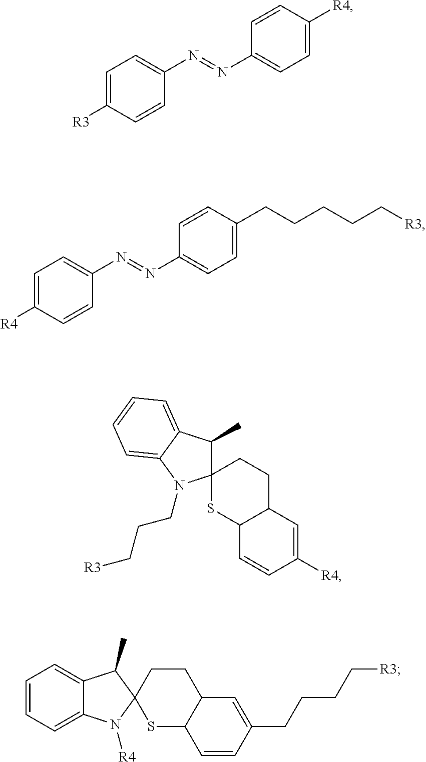

wherein R3 is the coordination group, and R4 is a free end.

In an exemplary embodiment, the free end may contain a siloxane group.

In an exemplary embodiment, the ligand may be:

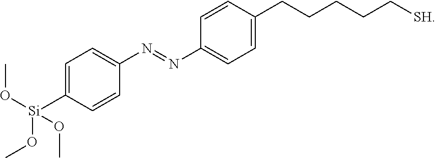 [SMILES: CO[Si](OC)(OC)c1ccc(/N=N/c2ccc(CCCCCS)cc2)cc1]

In an exemplary embodiment, the material of the monomolecular layer may be configured such that the molecular configuration is converted from a cis-configuration to a trans-configuration under an 80° C.-150° C. heating condition.

In an exemplary embodiment, the carrier transport layer may be an electron transport layer and includes an inorganic metal oxide nanoparticle thin film or an inorganic metal oxide thin film, wherein the inorganic metal oxide may be selected from any one or more of ZnO, TiO₂, SnO₂, and ZrO₂;
wherein ZnO may include metal-doped ZnO, and metal doped in the metal-doped ZnO may be selected from any one or more of Mg, Al, Zr, and Y.

In an exemplary embodiment, the electron transport layer may include a red sub-pixel electron transport layer, a green sub-pixel electron transport layer, and a blue sub-pixel electron transport layer;
the red sub-pixel electron transport layer is an inorganic metal oxide nanoparticle thin film or an inorganic metal oxide thin film, wherein the inorganic metal oxide may be ZnO or ZnMgO;
the green sub-pixel electron transport layer is an inorganic metal oxide nanoparticle thin film or an inorganic metal oxide thin film, wherein the inorganic metal oxide may be ZnO or ZnMgO;
the blue sub-pixel electron transport layer is an inorganic metal oxide nanoparticle thin film or an inorganic metal oxide thin film, wherein the inorganic metal oxide may be ZnO or ZnMgO.

In an exemplary embodiment, the red sub-pixel electron transport layer, the green sub-pixel electron transport layer, and the blue sub-pixel electron transport layer may be a ZnMgO nanoparticle thin film or a ZnMgO thin film, a weight percent content of Mg in ZnMgO of the red sub-pixel electron transport layer is less than a weight percent content of Mg in ZnMgO of the green sub-pixel electron transport layer, and the weight percent content of Mg in ZnMgO of the green sub-pixel electron transport layer is less than a weight percent content of Mg in ZnMgO of the blue sub-pixel electron transport layer.

In an exemplary embodiment, the weight percent content of Mg in ZnMgO of the red sub-pixel electron transport layer may be 1% to 5%, the weight percent content of Mg in ZnMgO of the green sub-pixel electron transport layer may be 5% to 10%, and the weight percent content of Mg in ZnMgO of the blue sub-pixel electron transport layer may be 10% to 20%.

In an exemplary embodiment,
the thickness of the red sub-pixel electron transport layer may be 40 nm to 300 nm, for example, may be 40 nm to 80 nm, and may also be, for example, 60 nm;
the thickness of the green sub-pixel electron transport layer may be 30 nm to 300 nm, for example, may be 30 nm to 80 nm, and may also be, for example, 30 nm, 40 nm, 50 nm or 80 nm;
the thickness of the blue sub-pixel electron transport layer may be 20 nm to 300 nm, for example, may be 20 nm to 40 nm or 40 nm to 80 nm.

In an exemplary embodiment, the carrier transport layer may be a hole transport layer, and a material of the hole transport layer may be selected from any one or more of an organic hole transport material and an inorganic metal oxide hole transport material;
the organic hole transport material may include any one or more of poly(9,9-dioctylfluorene-CO—N-(4-butylphenyl)diphenylamine) (TFB), polyvinylcarbazole (PVK), N,N′-bis(3-methylphenyl)-N,N′-diphenyl-1,1′-biphenyl-4,4′-diamine (TPD), and 4,4′-bis(9-carbazolyl)biphenyl (CBP);
the inorganic metal oxide hole transport material may include any one or more of NiO, NiO₂, and V₂O₅.

In an exemplary embodiment, the hole transport layer may include a first hole transport layer close to the quantum dot light-emitting layer and a second hole transport layer away from the quantum dot light-emitting layer, a material of the first hole transport layer is a first hole transport material, and a material of the second hole transport layer is a second hole transport material;

$$- 6.2 eV ⩽ \vert HOMO ( A ) \vert ⩽ - 5.5 eV ; - 5.5 eV ⩽ \vert HOMO ( B ) \vert ⩽ - 5. eV$$

wherein HOMO (A) is the highest occupied molecular orbital HOMO energy level of the first hole transport material, and HOMO (B) is the highest occupied molecular orbital HOMO energy level of the second hole transport material.

In an exemplary embodiment, the first hole transport material may be selected from any one or both of 4,4′,4″-tris(carbazol-9-yl)triphenylamine) (TCTA) and 4,4′-cyclohexylbis[N,N-bis(4-methylphenyl)aniline](TAPC), and the second hole transport material may be selected from any one or both of 4,4′-bis[N-(1-naphthyl)-N-phenylamino]biphenyl (NPB) and 4,4′,4″-tris(N-3-methylphenyl-N-phenylamino)triphenylamine (m-MTDATA).

In an exemplary embodiment, the thickness of the hole transport layer may be 20 nm to 60 nm, the thickness of the first hole transport layer may be T_{A}, 0 nm<T_{A}≤10 nm, and the thickness of the second hole transport layer may be T_{B}, 20 nm≤T_{B}≤60 nm; e.g., T_{A} may be 5 nm, and T_{B} may be 30 nm.

In an exemplary embodiment, the carrier transport layer may be located on both sides of the quantum dot light-emitting layer, the carrier transport layer on one side of the quantum dot light-emitting layer is an electron transport layer, and the carrier transport layer on the other side of the quantum dot light-emitting layer is a hole transport layer;
the electron transport layer may include an inorganic metal oxide nanoparticle thin film or an inorganic metal oxide thin film, wherein the inorganic metal oxide may be selected from any one or more of ZnO, TiO₂, SnO₂, and ZrO₂; wherein ZnO may include metal-doped ZnO, and metal doped in the metal-doped ZnO may be selected from any one or more of Mg, Al, Zr, and Y;
the material of the hole transport layer may be selected from any one or more of an organic hole transport material and an inorganic metal oxide hole transport material; wherein the organic hole transport material may include any one or more of poly(9,9-dioctylfluorene-CO—N-(4-butylphenyl)diphenylamine), polyvinylcarbazole, N,N′-bis(3-methylphenyl)-N,N′-diphenyl-1,1′-biphenyl-4,4′-diamine, and 4,4′-bis(9-carbazolyl)biphenyl; and the inorganic metal oxide hole transport material may include any one or more of NiO, NiO₂, and V₂O₅.

In an exemplary embodiment, the electron transport layer may include a red sub-pixel electron transport layer, a green sub-pixel electron transport layer, and a blue sub-pixel electron transport layer;
the red sub-pixel electron transport layer is an inorganic metal oxide nanoparticle thin film or an inorganic metal oxide thin film, wherein the inorganic metal oxide may be ZnO or ZnMgO;
the green sub-pixel electron transport layer is an inorganic metal oxide nanoparticle thin film or an inorganic metal oxide thin film, wherein the inorganic metal oxide may be ZnO or ZnMgO;
the blue sub-pixel electron transport layer is an inorganic metal oxide nanoparticle thin film or an inorganic metal oxide thin film, wherein the inorganic metal oxide may be ZnO or ZnMgO.

In an exemplary embodiment, the red sub-pixel electron transport layer, the green sub-pixel electron transport layer, and the blue sub-pixel electron transport layer may be a ZnMgO nanoparticle thin film or a ZnMgO thin film, a weight percent content of Mg in ZnMgO of the red sub-pixel electron transport layer is less than a weight percent content of Mg in ZnMgO of the green sub-pixel electron transport layer, and the weight percent content of Mg in ZnMgO of the green sub-pixel electron transport layer is less than a weight percent content of Mg in ZnMgO of the blue sub-pixel electron transport layer.

In an exemplary embodiment, the weight percent content of Mg in ZnMgO of the red sub-pixel electron transport layer may be 1% to 5%, the weight percent content of Mg in ZnMgO of the green sub-pixel electron transport layer may be 5% to 10%, and the weight percent content of Mg in ZnMgO of the blue sub-pixel electron transport layer may be 10% to 20%.

In an exemplary embodiment,
the thickness of the red sub-pixel electron transport layer may be 40 nm to 300 nm, for example, may be 40 nm to 80 nm, and may also be, for example, 60 nm;
the thickness of the green sub-pixel electron transport layer may be 30 nm to 300 nm, for example, may be 30 nm to 80 nm, and may also be, for example, 30 nm, 40 nm, 50 nm or 80 nm;
the thickness of the blue sub-pixel electron transport layer may be 20 nm to 300 nm, for example, may be 20 nm to 40 nm or 40 nm to 80 nm.

In an exemplary embodiment, the hole transport layer may include a first hole transport layer close to the quantum dot light-emitting layer and a second hole transport layer away from the quantum dot light-emitting layer, a material of the first hole transport layer is a first hole transport material, and a material of the second hole transport layer is a second hole transport material;

$$- 6.2 eV ⩽ \vert HOMO ( A ) \vert ⩽ - 5.5 eV ; - 5.5 eV ⩽ \vert HOMO ( B ) \vert ⩽ - 5. eV$$

wherein HOMO (A) is the highest occupied molecular orbital HOMO energy level of the first hole transport material, and HOMO (B) is the highest occupied molecular orbital HOMO energy level of the second hole transport material.

In an exemplary embodiment, the first hole transport material may be selected from any one or both of 4,4′,4″-tris(carbazol-9-yl)triphenylamine) (TCTA) and 4,4′-cyclohexylbis[N,N-bis(4-methylphenyl)aniline](TAPC), and the second hole transport material may be selected from any one or both of 4,4′-bis[N-(1-naphthyl)-N-phenylamino]biphenyl (NPB) and 4,4′,4″-tris(N-3-methylphenyl-N-phenylamino)triphenylamine (m-MTDATA).

In an exemplary embodiment, the thickness of the hole transport layer may be 20 nm to 60 nm, the thickness of the first hole transport layer may be T_{A}, 0 nm<T_{A}≤10 nm, and the thickness of the second hole transport layer may be T_{B}, 20 nm≤T_{B}≤60 nm; e.g., T_{A} may be 5 nm, and T_{B} may be 30 nm.

In an exemplary embodiment, the quantum dot light-emitting device may be in an upright structure or an inverted structure.

An embodiment of the present disclosure further provides a preparation method for the quantum dot light-emitting device described above, including:
forming a quantum dot light-emitting layer;
forming a carrier transport layer; and
forming a monomolecular layer between the carrier transport layer and the quantum dot light-emitting layer.

In an exemplary embodiment, the monomolecular layer is a self-assembled monomolecular layer, and the forming the monomolecular layer may include:
dissolving a material of the monomolecular layer in a solvent to form a solution containing the material of the monomolecular layer; and
forming the monomolecular layer from the solution containing the material of the monomolecular layer by means of film formation by soaking or spin coating.

In an exemplary embodiment, a temperature for the film formation by soaking may be room temperature, for example, may be 20° C. to 25° C., soaking time of the film formation by soaking may be 20 min to 50 min, and the solvent for dissolving the material of the monomolecular layer may be selected from any one or more of ethanol, ether, acetic acid, alkane, N,N-dimethylformamide (DMF), and dimethyl sulfoxide (DMSO).

In an exemplary embodiment, the material of the monomolecular layer is a ligand, and the preparation method may include:
providing an initial quantum dot containing an oil-soluble ligand;
performing ligand exchange by using the ligand with the oil-soluble ligand on a surface of the initial quantum dot to obtain a quantum dot containing a ligand; and
forming the quantum dot light-emitting layer and the monomolecular layer by using the quantum dot containing the ligand.

In an exemplary embodiment, the performing ligand exchange by using the ligand with the oil-soluble ligand on a surface of the initial quantum dot to obtain a quantum dot containing a ligand may include:
dissolving the ligand in an organic solvent to obtain a ligand solution;
adding the initial quantum dot into the ligand solution to obtain a ligand solution containing the initial quantum dot, stirring, and performing ligand exchange by using the ligand with the oil-soluble ligand on the surface of the initial quantum dot; and
adding the solution obtained after the ligand exchange into an undesirable solvent of the ligand so that the quantum dot containing the ligand is precipitated and separated from the solution.

In an exemplary embodiment, the organic solvent may be selected from any one or more of alcohol solvents, and the undesirable solvent of the ligand may be water. In an exemplary embodiment, after the quantum dot containing the ligand is precipitated, it may be separated from the solution by means of centrifugation, for example, the precipitate is separated from the upper solution by centrifugation, and after the upper solution is removed, an undesirable solvent is added again for centrifugation until the upper solution is clear, and the quantum dot containing the ligand may be obtained after the supernatant is removed.

An embodiment of the present disclosure further provides a quantum dot material, including: a quantum dot and a ligand for modifying the quantum dot, wherein the ligand is coordinately bound to the quantum dot, the ligand is configured in such a way that a molecular configuration is converted from a cis-configuration to a trans-configuration under a visible light irradiation condition or a heating condition, and the molecular configuration is converted from the trans-configuration to the cis-configuration under an ultraviolet irradiation condition, and a molecular chain length of the trans-configuration is greater than that of the cis-configuration.

The quantum dot material in an embodiment of the present disclosure is provided with a ligand which can undergo an isomerization reaction under a light irradiation condition or a heating condition. The ligand surrounds the quantum dot. When the quantum dot material of the embodiment of the present disclosure is used to prepare a quantum dot light-emitting layer of a quantum dot light-emitting device, ligands are contained between the quantum dot and an electron transport layer and between the quantum dot and a hole transport layer, and the ligand will undergo an isomerization reaction under a visible light irradiation condition or a heating condition, in which the molecular configuration of the ligand is converted from a cis-configuration to a trans-configuration, so that the spacing between the quantum dot transport layer and the electron transport layer and the spacing between the quantum dot light-emitting layer and the hole transport layer are increased, thereby achieving the effects of weakening electron injection and reducing quenching of quantum dots, and improving the light-emitting efficiency.

In an exemplary embodiment, the ligand may be configured such that the molecular configuration is converted from a cis-configuration to a trans-configuration under an 80° C.-150° C. heating condition.

In an exemplary embodiment, the ligand may contain at least one of an azo group and

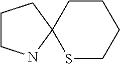

group.

In an exemplary embodiment, a general structural formula of the ligand may be:

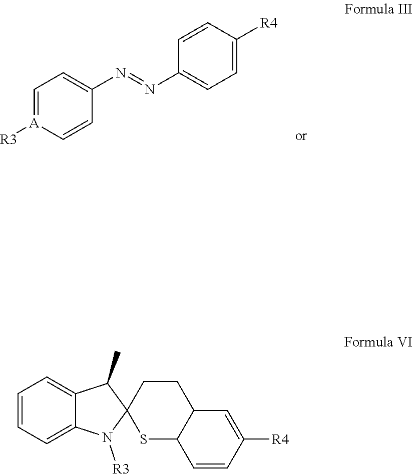

wherein, A in Formula III is a carbon atom or an ammonium ion, and when A in Formula III is an ammonium ion, Formula III further includes a halogen anion which is selected from at least one of F⁻, Cl⁻, Br⁻ and I⁻; in Formula III and Formula VI, one of R3 and R4 contains a coordination group capable of being coordinately bound to the quantum dot, and the other one of R3 and R4 is a free end, and the coordination group may be selected from any one or more of mercapto group, hydroxyl group, amine group, amino group, carboxyl group, ester group, phosphine group and phosphoroxy group, for example, the coordination group may be selected from any one or more of mercapto group, amine group, and carboxyl group; the free end may be any group, for example, it may be alkyl group, —NH₂, amine group, alcoholamine group, —NO₂, —COOH or a group containing a carbon-carbon double bond.

In an exemplary embodiment, the quantum dot material may be selected from any one or more of:

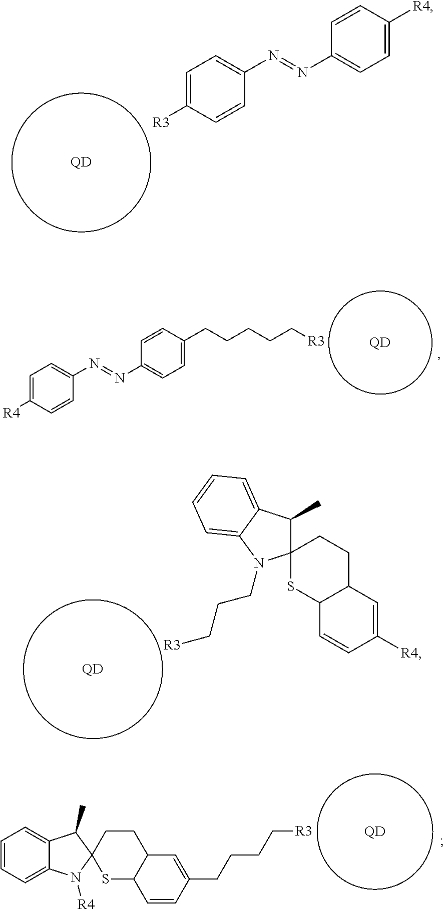

wherein R3 is the coordination group, and R4 is a free end.

In an exemplary embodiment, the free end may contain a siloxane group.

In an exemplary embodiment, the ligand may be:

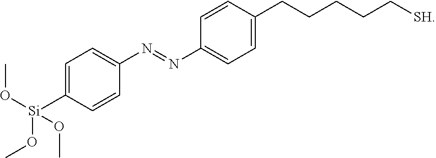 [SMILES: CO[Si](OC)(OC)c1ccc(/N=N/c2ccc(CCCCCS)cc2)cc1]

An embodiment of the present disclosure further provides a preparation method for the quantum dot material described above, including:
providing an initial quantum dot containing an oil-soluble ligand; and
performing ligand exchange by using the ligand with the oil-soluble ligand on a surface of the initial quantum dot to obtain the quantum dot material.

In an exemplary embodiment, the performing ligand exchange by using the ligand with the oil-soluble ligand on a surface of the initial quantum dot to obtain the quantum dot material may include:
dissolving the ligand in an organic solvent to obtain a ligand solution;
adding the initial quantum dot into the ligand solution to obtain a ligand solution containing the initial quantum dot, stirring, and performing ligand exchange by using the ligand with the oil-soluble ligand on the surface of the initial quantum dot; and
adding the solution obtained after the ligand exchange into an undesirable solvent of the ligand so that the quantum dot containing the ligand is precipitated and separated from the solution to obtain the quantum dot material.

In an exemplary embodiment, the organic solvent may be selected from any one or more of alcohol solvents, and the undesirable solvent of the ligand may be water.

In an exemplary embodiment, after the quantum dot containing the ligand is precipitated, it may be separated from the solution by means of centrifugation, for example, the precipitate is separated from the upper solution by centrifugation, and after the upper solution is removed, an undesirable solvent is added again for centrifugation until the upper solution is clear, and the quantum dot material may be obtained after the supernatant is removed.

An embodiment of the present disclosure further provides a quantum dot light-emitting device, wherein the quantum dot light-emitting device includes a quantum dot light-emitting layer, and a material of the quantum dot light-emitting layer is the quantum dot material described above.

In an exemplary embodiment, the quantum dot light-emitting device may be in an inverted structure.

FIG. 5 is a schematic structural diagram of a QLED device in an inverted structure according to an exemplary embodiment of the present disclosure. As shown in FIG. 5, the QLED device in an inverted structure may include: a cathode 700, an electron transport layer 600 disposed on the cathode 700, a monomolecular layer 500 disposed on a side of the electron transport layer 600 away from the cathode 700, a quantum dot light-emitting layer 400 disposed on a side of the monomolecular layer 500 away from the cathode 700, a hole transport layer 300 disposed on a side of the quantum dot light-emitting layer 400 away from the cathode 700, a hole injection layer 200 disposed on a side of the hole transport layer 300 away from the cathode 700, and an anode 100 disposed on a side of the hole injection layer 200 away from the cathode 700.

FIG. 6 is a schematic structural diagram of a QLED device in an inverted structure according to another exemplary embodiment of the present disclosure. As shown in FIG. 6, the QLED device in an inverted structure may include: a cathode 700, an electron transport layer 600 disposed on the cathode 700, a quantum dot light-emitting layer 400 disposed on a side of the electron transport layer 600 away from the cathode 700, a monomolecular layer 500 disposed on a side of the quantum dot light-emitting layer 400 away from the cathode 700, a hole transport layer 300 disposed on a side of the monomolecular layer 500 away from the cathode 700, a hole injection layer 200 disposed on a side of the hole transport layer 300 away from the cathode 700, and an anode 100 disposed on a side of the hole injection layer 200 away from the cathode 700.

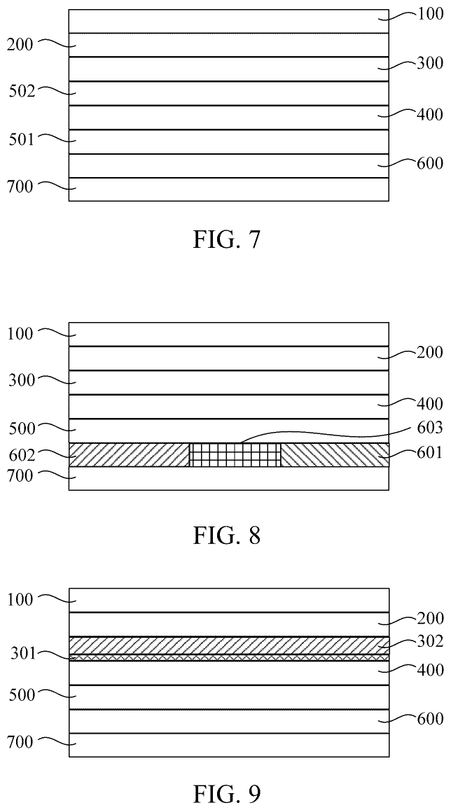

FIG. 7 is a schematic structural diagram of a QLED device in an inverted structure according to a further exemplary embodiment of the present disclosure. As shown in FIG. 7, the QLED device in an inverted structure may include: a cathode 700, an electron transport layer 600 disposed on the cathode 700, a first monomolecular layer 501 disposed on a side of the electron transport layer 600 away from the cathode 700, a quantum dot light-emitting layer 400 disposed on a side of the first monomolecular layer 501 away from the cathode 700, a second monomolecular layer 502 disposed on a side of the quantum dot light-emitting layer 400 away from the cathode 700, a hole transport layer 300 disposed on a side of the second monomolecular layer 502 away from the cathode 700, a hole injection layer 200 disposed on a side of the hole transport layer 300 away from the cathode 700, and an anode 100 disposed on a side of the hole injection layer 200 away from the cathode 700.

In an exemplary embodiment, in a QLED device in the inverted structure,
The cathode 700 may be formed of a transparent conductive material or a conductive polymer deposited on a substrate, or may be a metal electrode such as Al, Ag. The transparent conductive material may be selected from Indium Tin Oxide (ITO), Indium Zinc Oxide (IZO), F-doped Tin Oxide (FTO), etc., and the substrate may be a flexible substrate such as glass or Polyethylene Terephthalate (PET);
the electron transport layer 600 may be an inorganic metal oxide nanoparticle thin film or an inorganic metal oxide thin film, wherein the inorganic metal oxide is selected from any one or more of ZnO, TiO₂, SnO₂, and ZrO₂; the inorganic metal oxide nanoparticle thin film may be obtained by depositing or spin coating inorganic metal oxide nanoparticles by a magnetron sputtering method;
for example, the electron transport layer 600 may be a zinc oxide nanoparticle thin film or a zinc oxide thin film,
the material of the electron transport layer 600 may also be ion-doped zinc oxide nanoparticles, e.g., Mg, Al, Zr, or Y doped zinc oxide nanoparticles, etc.

FIG. 8 is a schematic diagram of an arrangement of an electron transport layer of the QLED device in an inverted structure shown in FIG. 5; as shown in FIG. 8, the electron transport layer 600 may include a red sub-pixel electron transport layer 601, a green sub-pixel electron transport layer 602, and a blue sub-pixel electron transport layer 603, the thickness of the three sub-pixel electron transport layers may be set as required, which may be between 20 nm and 300 nm, for example, may be between 30 nm and 80 nm.

For example, the red sub-pixel electron transport layer 601 is an inorganic metal oxide nanoparticle thin film or an inorganic metal oxide thin film, wherein the inorganic metal oxide is ZnO or ZnMgO, the weight percent content of Mg in ZnMgO is 1% to 5%, and the thickness of the red sub-pixel electron transport layer 601 may be 40 nm to 300 nm, for example, may be 40 nm to 80 nm, and for example, may also be 60 nm.

The green sub-pixel electron transport layer 602 is an inorganic metal oxide nanoparticle thin film or an inorganic metal oxide thin film, wherein the inorganic metal oxide is ZnO or ZnMgO, the weight percent content of Mg in ZnMgO is 5% to 10%, and the thickness of the green sub-pixel electron transport layer 602 may be 30 nm to 300 nm, for example, may be 30 nm to 80 nm, and for example, may also be 30 nm, 40 nm, 50 nm, or 80 nm.

The blue sub-pixel electron transport layer 603 is an inorganic metal oxide nanoparticle thin film or an inorganic metal oxide thin film, wherein the inorganic metal oxide is ZnO or ZnMgO, the weight percent content of Mg in ZnMgO is 10% to 20%, and the thickness of the blue sub-pixel electron transport layer 603 may be 20 nm to 300 nm, for example, may be 20 nm to 40 nm or 40 nm to 80 nm.

The quantum dot light-emitting layer 400 may be prepared by spin coating, evaporation, ink jet printing, electronic jet printing and the like, and the quantum dot for preparing the quantum dot light-emitting layer may be selected from any one or more of CdS, CdSe, ZnSe, InP, PbS, CsPbCl₃, CsPbBr₃, CsPhI₃, CdS/ZnS, CdSe/ZnS, ZnSe, ZnTeSe, ZnSe/ZnS, ZnTeSe/ZnS, InP/ZnS, PbS/ZnS, CsPbCl₃/ZnS, CsPbBr₃/ZnS and CsPhI₃/ZnS; and the thickness of the quantum dot light-emitting layer 400 may be 20 nm to 50 nm, for example, may be 30 nm or 40 nm.

The material of the hole transport layer 300 may be selected from any one or more of an organic hole transport material and an inorganic metal oxide hole transport material; the organic hole transport material may include poly(9,9-dioctylfluorene-CO—N-(4-butylphenyl)diphenylamine) (TFB), polyvinylcarbazole (PVK), N,N′-bis(3-methylphenyl)-N,N′-diphenyl-1,1′-biphenyl-4,4′-diamine (TPD), and 4,4′-bis(9-carbazolyl)biphenyl (CBP); and the inorganic metal oxide hole transport material may include NiO, NiO₂, and V₂O₅.

The hole transport layer 300 may be a single layer formed of one material or a composite layer formed by stacking layers of a plurality of materials; FIG. 9 is a schematic diagram of an arrangement of a hole transport layer of the QLED device in an inverted structure shown in FIG. 5; as shown in FIG. 9, the hole transport layer 200 may include a first hole transport layer 301 close to the quantum dot light-emitting layer and a second hole transport layer 302 away from the quantum dot light-emitting layer, the material of the first hole transport layer 301 is a first hole transport material and the material of the second hole transport layer 302 is a second hole transport material;

$$- 6.2 eV ⩽ \vert HOMO ( A ) \vert ⩽ - 5.5 eV ; - 5.5 eV ⩽ \vert HOMO ( B ) \vert ⩽ - 5. eV$$

wherein HOMO (A) is the highest occupied molecular orbital HOMO energy level of the first hole transport material, and HOMO (B) is the highest occupied molecular orbital HOMO energy level of the second hole transport material.

The thickness of the hole transport layer may be 20 nm to 60 nm, for example, may be 25 nm to 35 nm; the thickness of the first hole transport layer 301 may be T_{A}, 0 nm<T_{A}≤10 nm, the thickness of the second hole transport layer 302 may be T_{B}, 20 nm≤T_{B}≤60 nm; e.g., T_{A} may be 5 nm, and T_{B} may be 30 nm.

The material of the hole injection layer 200 may be selected from PEDOT:PSS (poly(3,4-ethylenedioxythiophene)/polystyrene sulfonate), HAT-CN (2,3,6,7,10,11-hexocyano-1,4,5,8,9,12-hexaazabenzophenanthrene), etc.; and may also be an inorganic metal oxide or sulfide material, such as NiO, MoO₃, WoO₃, V₂O₅, CuO, CuS, CuSCN, Cu:NiO; and may be prepared by spin coating, evaporation, inkjet printing, etc.; the thickness of the hole injection layer 200 may be 3 nm to 10 nm, for example, may be 3 nm, 5 nm, 7 nm, or 10 nm.

The anode 100 may be prepared by evaporation or sputtering, and may be a metal (e.g., Al, Ag, etc.) or IZO film; and may have a thickness of 10 nm to 100 nm.

In an exemplary embodiment, the quantum dot light-emitting device may be in an upright structure.

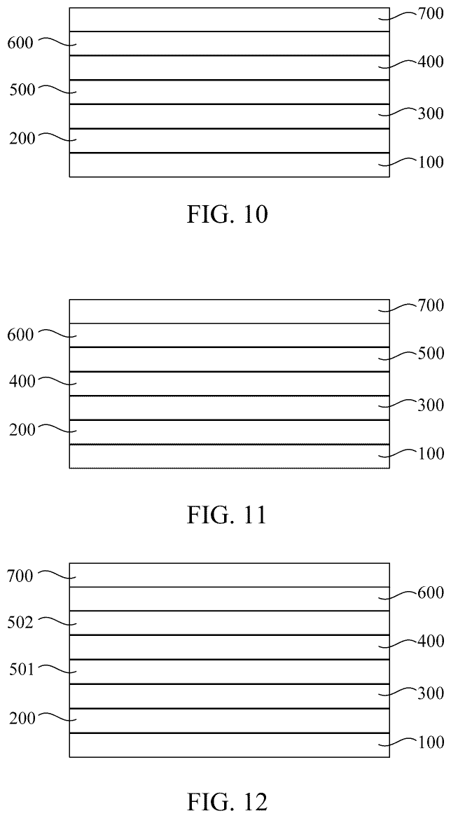

FIG. 10 is a schematic structural diagram of a QLED device in an upright structure according to an exemplary embodiment of the present disclosure. As shown in FIG. 10, the QLED device in an upright structure may include an anode 100, a hole injection layer 200 disposed on the anode 100, a hole transport layer 300 disposed on a side of the hole injection layer 200 away from the anode 100, a monomolecular layer 500 disposed on a side of the hole transport layer 300 away from the anode 100, a quantum dot light-emitting layer 400 disposed on a side of the monomolecular layer 500 away from the anode 100, an electron transport layer 600 disposed on a side of the quantum dot light-emitting layer 400 away from the anode 100, and a cathode 700 disposed on a side of the electron transport layer 600 away from the anode 100.

FIG. 11 is a schematic structural diagram of a QLED device in an upright structure according to another exemplary embodiment of the present disclosure. As shown in FIG. 11, the QLED device in an upright structure may include an anode 100, a hole injection layer 200 disposed on the anode 100, a hole transport layer 300 disposed on a side of the hole injection layer 200 away from the anode 100, a quantum dot light-emitting layer 400 disposed on a side of the hole transport layer 300 away from the anode 100, a monomolecular layer 500 disposed on a side of the quantum dot light-emitting layer 400 away from the anode 100, an electron transport layer 600 disposed on a side of the monomolecular layer 500 away from the anode 100, and a cathode 700 disposed on a side of the electron transport layer 600 away from the anode 100.

FIG. 12 is a schematic structural diagram of a QLED device in an upright structure according to a further exemplary embodiment of the present disclosure. As shown in FIG. 12, the QLED device in an upright structure may include an anode 100, a hole injection layer 200 disposed on the anode 100, a hole transport layer 300 disposed on a side of the hole injection layer 200 away from the anode 100, a first monomolecular layer 501 disposed on a side of the hole transport layer 300 away from the anode 100, a quantum dot light-emitting layer 400 disposed on a side of the first monomolecular layer 501 away from the anode 100, a second monomolecular layer 502 disposed on a side of the quantum dot light-emitting layer 400 away from the anode 100, an electron transport layer 600 disposed on a side of the second monomolecular layer 502 away from the anode 100, and a cathode 700 disposed on a side of the electron transport layer 600 away from the anode 100.

In an exemplary embodiment, in the QLED device in an upright structure,
the anode 100 may be formed of a transparent conductive material or a conductive polymer deposited on a substrate, or may be a metal electrode such as Al, Ag. The transparent conductive material may be selected from Indium Tin Oxide (ITO), Indium Zinc Oxide (IZO), F-doped Tin Oxide (FTO), etc., and the substrate may be a flexible substrate such as glass or Polyethylene Terephthalate (PET);
the cathode 700 may be prepared by evaporation or sputtering, and may be a metal (e.g., Al, Ag, etc.) or IZO film; and may have a thickness of 10 nm to 100 nm;
the hole injection layer 200, the hole transport layer 300, the quantum dot light-emitting layer 400, and the electron transport layer 600 may be prepared by a same material and a same method as the material and method for the QLED device in an inverted structure.

An embodiment of the present disclosure further provides a display apparatus, including a plurality of quantum dot light-emitting devices described above.

The display apparatus may be any product or component with a display function, such as a mobile phone, a tablet computer, a television, a display, a laptop computer, a digital photo frame, a navigator, a vehicle-mounted display, a smart watch, and a smart bracelet.

An exemplary embodiment of the present disclosure provides a quantum dot light-emitting device having an inverted structure shown in FIG. 5, and a preparation method therefor includes:
(1) depositing a first electrode (a cathode) on a substrate, wherein the substrate may be a flexible substrate such as glass or PET, and the first electrode may be a transparent conductive material ITO, FTO or a conductive polymer, etc., or may be an opaque metal electrode, such as Al and Ag;
(2) depositing ZnO or ZnO nanoparticles doped with Mg, Al, Zr, Y, etc. (or directly spin coating ZnO nanoparticles) on the first electrode by magnetron sputtering to form a ZnO nanoparticle thin film as an electron transport layer; wherein the electron transport layer may include a red sub-pixel electron transport layer, a green sub-pixel electron transport layer and a blue sub-pixel electron transport layer, the thickness of the three sub-pixel electron transport layers may be set as required, which may be between 20 nm and 300 nm, for example, may be between 30 nm and 80 nm; for example, the red sub-pixel electron transport layer is a ZnO or ZnMgO nanoparticle thin film, the weight percent content of Mg in ZnMgO is 1% to 5%, and the thickness of the red sub-pixel electron transport layer is 40 nm to 300 nm, for example, it may be 40 nm to 80 nm, and for example, it may also be 60 nm; the green sub-pixel electron transport layer is a ZnO or ZnMgO nanoparticle thin film, the weight percent content of Mg in ZnMgO is 5% to 10%, the thickness of the green sub-pixel electron transport layer is 30 nm to 300 nm, for example, it may be 30 nm to 80 nm, and for example, it may also be 30 nm, 40 nm, 50 nm, or 80 nm; and the blue sub-pixel electron transport layer is a ZnO or ZnMgO nanoparticle thin film, the weight percent content of Mg in ZnMgO is 10% to 20%, the thickness of the blue sub-pixel electron transport layer is 20 nm to 300 nm, for example, the thickness is 20 nm to 40 nm or 40 nm to 80 nm;
(3) preparing a self-assembled monomolecular layer on the electron transport layer: soaking the substrate on which the ZnO nanoparticle thin film has been prepared into a solution containing a material of the self-assembled monomolecular layer to form SAMs; wherein the solution containing the material of the self-assembled monomolecular layer is formed by the material of the self-assembled monomolecular layer and a solvent, the solvent may be selected from any one or more of ethanol, ether, and acetic acid, when the material of the self-assembled monomolecular layer contains alkyl group, the solvent may be selected from any one or more of ethanol, ether, acetic acid, alkanes (e.g., cyclohexane), N,N-dimethylformamide (DMF), and dimethyl sulfoxide (DMSO); the time for the substrate to be soaked in the solution containing the material of the self-assembled monomolecular layer may be 20 min to 50 min, for example, 30 min; in addition, SAMs may also be formed by spin coating;
the material of the self-assembled monomolecular layer is configured in such a way that a molecular configuration is converted from a cis-configuration to a trans-configuration under a visible light irradiation condition or a heating condition, and the molecular configuration is converted from the trans-configuration to the cis-configuration under an ultraviolet irradiation condition, and a molecular chain length of the trans-configuration is greater than that of the cis-configuration; the temperature of the heating may be 80° C. to 150° C.; and the general structural formula of the material of the self-assembled monomolecular layer may be:

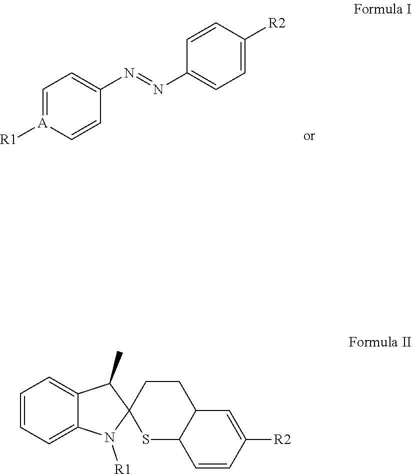

wherein, A in Formula I is a carbon atom or an ammonium ion, and when A in Formula I is an ammonium ion, Formula I further includes a halogen anion which is selected from at least one of F⁻, Cl⁻, Br⁻ and I⁻; R1 and R2 in Formula I and Formula II are each independently selected from at least one of alkyl group, —NH₂, amine group (e.g., monoalkylamine group, dialkylamine group), alcoholamine group (e.g., —N(C₂H₄OH)₂, —N(CH₂OH)₂, —NHC₂H₄OH), —NO₂, —COOH, and a group containing a carbon-carbon double bond (e.g., —CH═CH₂), herein, there is no requirement for a carbon chain length of alkyl group, for example, the carbon chain length of alkyl group may be 4 to 8;
for example, the material of the self-assembled monomolecular layer is selected from any one or more of the following compounds:

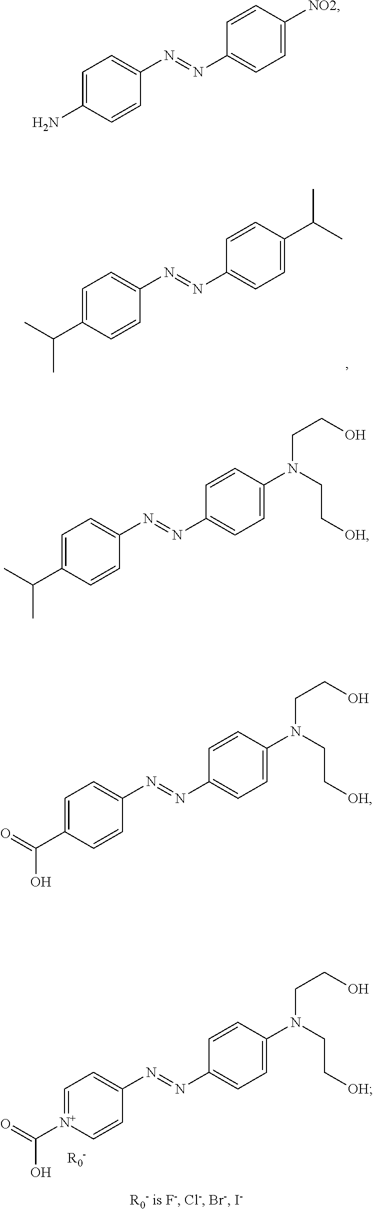

(4) preparing a quantum dot light-emitting layer on the self-assembled monomolecular layer: sequentially preparing a red quantum dot light-emitting layer, a green quantum dot light-emitting layer, and a blue quantum dot light-emitting layer on the self-assembled monomolecular layers corresponding to the red sub-pixel electron transport layer, the green sub-pixel electron transport layer and the blue sub-pixel electron transport layer by means of ink jet printing, or photolithography, etc., wherein the thickness of the three quantum dot light-emitting layers may all be in a range of 20 nm to 50 nm, for example, may be 30 nm or 40 nm;
(5) sequentially depositing a hole transport layer and a hole injection layer on the quantum dot layer, wherein the material of the hole transport layer may be an organic hole transport material, e.g., TFB, PVK, TPD, CBP, etc., or may be an inorganic metal oxide, e.g., NiO, NiO₂, and V₂O₅; the hole transport layer may be a single layer formed of one material or a composite layer formed by stacking layers of a plurality of materials, for example, the hole transport layer may include a first hole transport layer close to the quantum dot light-emitting layer and a second hole transport layer away from the quantum dot light-emitting layer, the material of the first hole transport layer is a first hole transport material, −6.2 eV≤|HOMO(A)|≤−5.5 eV; the material of the second hole transport layer is a second hole transport material, −5.5 eV≤|HOMO(B)|≤−5.0 eV;
the thickness of the hole transport layer may be 20 nm to 60 nm, for example, may be 25 nm to 35 nm; the thickness of the first hole transport layer may be T_{A}, 0 nm<T_{A}≤10 nm, and the thickness of the second hole transport layer may be T_{B}, 20 nm≤T_{B}≤60 nm; e.g., T_{A} may be 5 nm, T_{B} may be 30 nm;
the material of the hole injection layer may be selected from PEDOT:PSS, HAT-CN, etc.; and may also be an inorganic metal oxide or sulfide material, e.g., NiO, MoO₃, WoO₃, V₂O₅, CuO, CuS, CuSCN, Cu:NiO, etc.; and may be prepared by spin coating, evaporation, inkjet printing, etc.;
the thickness of the hole injection layer may be 3 nm to 10 nm, for example, may be 3 nm, 5 nm, 7 nm, or 10 nm; and
(6) preparing a second electrode (an anode) on the hole injection layer: wherein the second electrode may be metal Al, Ag, etc., or an IZO film may be deposited by magnetron sputtering, and its thickness may be 10 nm to 100 nm.

An exemplary embodiment of the present disclosure provides a quantum dot light-emitting device having an inverted structure shown in FIG. 7, and a preparation method therefor includes:
(1) depositing a first electrode (a cathode) on a substrate, wherein the substrate may be a flexible substrate such as glass or PET, and the first electrode may be a transparent conductive material ITO, FTO or a conductive polymer, etc., or may be an opaque metal electrode, such as Al and Ag;
(2) depositing ZnO or ZnO nanoparticles doped with Mg, Al, Zr, Y, etc. (or directly spin coating ZnO nanoparticles) on the first electrode by magnetron sputtering to form a ZnO nanoparticle thin film as an electron transport layer; wherein the electron transport layer may include a red sub-pixel electron transport layer, a green sub-pixel electron transport layer and a blue sub-pixel electron transport layer, the thickness of the three sub-pixel electron transport layers may be set as required, which may be between 20 nm and 300 nm, for example, may be between 30 nm and 80 nm; for example, the red sub-pixel electron transport layer is a ZnO or ZnMgO nanoparticle thin film, the weight percent content of Mg in ZnMgO is 1% to 5%, and the thickness of the red sub-pixel electron transport layer is 40 nm to 300 nm, for example, it may be 40 nm to 80 nm, and for example, it may also be 60 nm; the green sub-pixel electron transport layer is a ZnO or ZnMgO nanoparticle thin film, the weight percent content of Mg in ZnMgO is 5% to 10%, the thickness of the green sub-pixel electron transport layer is 30 nm to 300 nm, for example, it may be 30 nm to 80 nm, and for example, it may also be 30 nm, 40 nm, 50 nm, or 80 nm; and the blue sub-pixel electron transport layer is a ZnO or ZnMgO nanoparticle thin film, the weight percent content of Mg in ZnMgO is 10% to 20%, the thickness of the blue sub-pixel electron transport layer is 20 nm to 300 nm, for example, the thickness is 20 nm to 40 nm or 40 nm to 80 nm;
(3) sequentially preparing a red quantum dot light-emitting layer with a monomolecular layer, a green quantum dot light-emitting layer with a monomolecular layer and a blue quantum dot light-emitting layer with a monomolecular layer on the red sub-pixel electron transport layer, the green sub-pixel electron transport layer and the blue sub-pixel electron transport layer by means of ink jet printing, or photolithography, etc., wherein the thickness of the three quantum dot light-emitting layers may all be in a range of 20 nm to 50 nm, for example, may be 30 nm or 40 nm;
wherein the quantum dot of the quantum dot light-emitting layer has a ligand, so at the time of forming the quantum dot light-emitting layer, the ligand forms a monomolecular layer; the ligand is configured in such a way that a molecular configuration is converted from a cis-configuration to a trans-configuration under a visible light irradiation condition or a heating condition, and the molecular configuration is converted from the trans-configuration to the cis-configuration under an ultraviolet irradiation condition, and a molecular chain length of the trans-configuration is greater than that of the cis-configuration; the temperature of the heating may be 80° C. to 150° C.;
the general structural formula of the ligand may be:

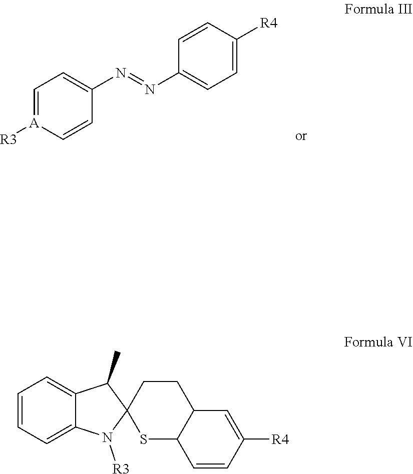

wherein, A in Formula III is a carbon atom or an ammonium ion, and when A in Formula III is an ammonium ion, Formula III further includes a halogen anion which is selected from at least one of F⁻, Cl⁻, Br⁻ and I⁻; in Formula III and Formula VI, one of R3 and R4 contains a coordination group capable of being coordinately bound to the quantum dot, and the other one of R3 and R4 is a free end, and the coordination group is selected from any one or more of mercapto group, hydroxyl group, amine group, amino group, carboxyl group, ester group, phosphine group and phosphoroxy group, for example, the coordination group may be selected from any one or more of mercapto group, amine group, and carboxyl group; the free end may contain a siloxane group; the free end may be any group, for example, it may be alkyl group, —NH₂, amine group, alcoholamine group, —NO₂, —COOH or a group containing a carbon-carbon double bond;
the ligand-containing quantum dot may be selected from any one or more of the following:

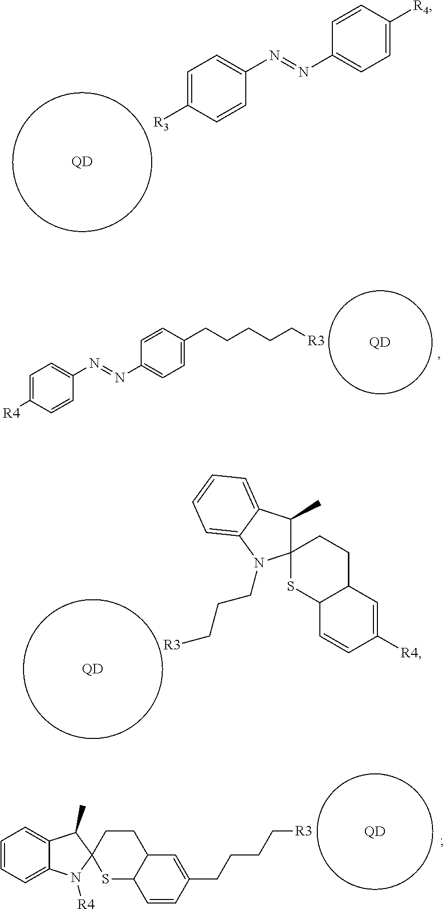

the quantum dot with a ligand may be prepared by the following method: providing an initial quantum dot containing an oil-soluble ligand (e.g., oleic acid, etc.); dissolving the ligand in an organic solvent (which, for example, may be selected from any one or more of alcoholic solvents) to obtain a ligand solution; adding the initial quantum dot into the ligand solution to obtain a ligand solution containing the initial quantum dot, stirring, and performing ligand exchange by using the ligand with the oil-soluble ligand on the surface of the initial quantum dot; adding the solution obtained after the ligand exchange into an undesirable solvent of the ligand (for example, deionized water may be selected) to precipitate the quantum dot containing the ligand, separating the precipitate from an upper solution by centrifugation, removing the upper solution, then adding the undesirable solvent again for centrifugation until the upper solution is clear, and removing the supernatant to obtain the quantum dot with the ligand;
(4) sequentially depositing a hole transport layer and a hole injection layer on a monomolecular layer away from the electron transport layer; and
(5) preparing a second electrode (an anode) on the hole injection layer: wherein the second electrode may be metal Al, Ag, etc., or an IZO film may be deposited by magnetron sputtering, and its thickness may be 10 nm to 100 nm.

An exemplary embodiment of the present disclosure provides a quantum dot light-emitting device having an upright structure shown in FIG. 10, and a preparation method therefor includes:
(1) depositing a first electrode (an anode) on a substrate, wherein the substrate may be a flexible substrate such as glass or PET, and the first electrode may be a transparent conductive material ITO, FTO or a conductive polymer, etc., or may be an opaque metal electrode, such as Al and Ag;
(2) sequentially preparing a hole injection layer and a hole transport layer on the first electrode;
wherein the material of the hole injection layer may be selected from PEDOT:PSS, HAT-CN, etc.; and may also be an inorganic metal oxide or sulfide material, e.g., NiO, MoO₃, WoO₃, V₂O₅, CuO, CuS, CuSCN, Cu:NiO, etc.; and may be prepared by spin coating, evaporation, inkjet printing, etc.; the thickness of the hole injection layer may be from 3 nm to 7 nm, for example, may be 5 nm;
wherein the material of the hole transport layer may be an organic hole transport material, e.g., TFB, PVK, TPD, CBP, etc., or may be an inorganic metal oxide, e.g., NiO, NiO₂, and V₂O₅; the hole transport layer may be a single layer formed of one material or a composite layer formed by stacking layers of a plurality of materials, for example, the hole transport layer may include a first hole transport layer close to the quantum dot light-emitting layer and a second hole transport layer away from the quantum dot light-emitting layer, the material of the first hole transport layer is a first hole transport material, −6.2 eV≤|HOMO(A)|≤−5.5 eV; the material of the second hole transport layer is a second hole transport material, −5.5 eV≤|HOMO(B)|≤−5.0 eV;
the thickness of the hole transport layer may be 20 nm to 60 nm, for example, may be 25 nm to 35 nm; the thickness of the first hole transport layer may be T_{A}, 0 nm<T_{A}≤10 nm, and the thickness of the second hole transport layer may be T_{B}, 20 nm≤T_{B}≤60 nm; e.g., T_{A} may be 5 nm, T_{B} may be 30 nm;
(3) preparing a self-assembled monomolecular layer on the hole transport layer: soaking the substrate on which the hole transport layer has been prepared into a solution containing a material of the self-assembled monomolecular layer to form SAMs; wherein the solution containing the material of the self-assembled monomolecular layer is formed by the material of the self-assembled monomolecular layer and a solvent, the solvent may be selected from any one or more of ethanol, ether, and acetic acid, when the material of the self-assembled monomolecular layer contains alkyl group, the solvent may be selected from any one or more of ethanol, ether, acetic acid, alkanes (e.g., cyclohexane), N,N-dimethylformamide (DMF), and dimethyl sulfoxide (DMSO); the time for the substrate to be soaked in the solution containing the material of the self-assembled monomolecular layer may be 20 min to 50 min, for example, 30 min; in addition, SAMs may also be formed by spin coating;
the material of the self-assembled monomolecular layer is configured in such a way that a molecular configuration is converted from a cis-configuration to a trans-configuration under a visible light irradiation condition or a heating condition, and the molecular configuration is converted from the trans-configuration to the cis-configuration under an ultraviolet irradiation condition, and a molecular chain length of the trans-configuration is greater than that of the cis-configuration; the temperature of the heating may be 80° C. to 150° C.; and the general structural formula of the material of the self-assembled monomolecular layer may be:

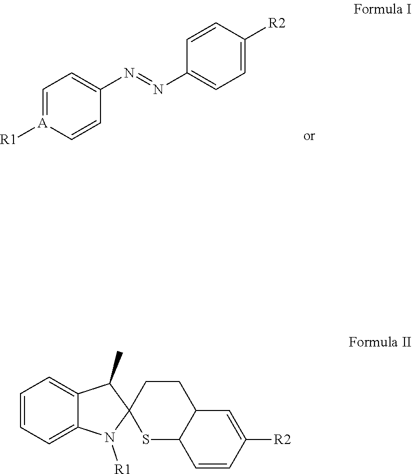

wherein, A in Formula I is a carbon atom or an ammonium ion, and when A in Formula I is an ammonium ion, Formula I further includes a halogen anion which is selected from at least one of F⁻, Cl⁻, Br⁻ and I⁻; R1 and R2 in Formula I and Formula II are each independently selected from at least one of alkyl group, —NH₂, amine group (e.g., monoalkylamine group, dialkylamine group), alcoholamine group (e.g., —N(C₂H₄OH)₂, —N(CH₂OH)₂, —NHC₂H₄OH), —NO₂, —COOH, and a group containing a carbon-carbon double bond (e.g., —CH═CH₂), herein, there is no requirement for a carbon chain length of alkyl group, for example, the carbon chain length of alkyl group may be 4 to 8;
for example, the material of the self-assembled monomolecular layer is selected from any one or more of the following compounds:

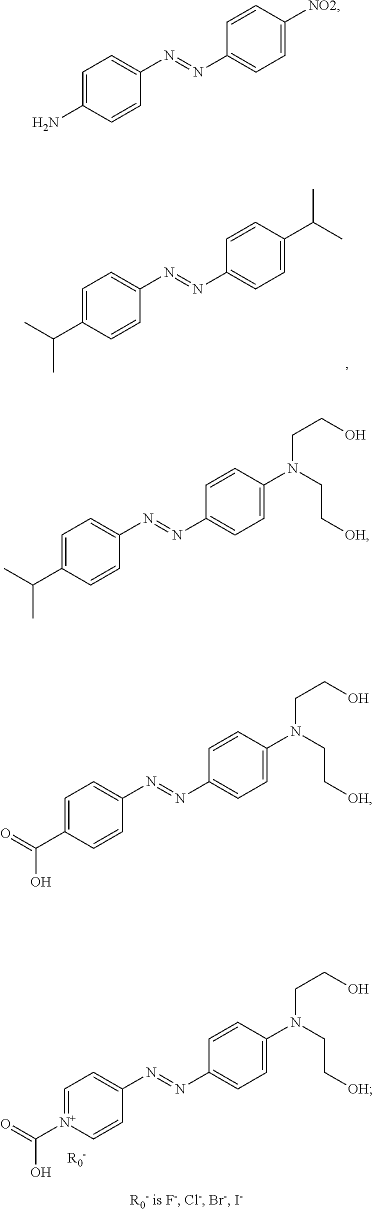

(4) preparing a quantum dot light-emitting layer on the self-assembled monomolecular layer: wherein the quantum dot light-emitting layer may include a red quantum dot light-emitting layer, a green quantum dot light-emitting layer and a blue quantum dot light-emitting layer, the three quantum dot light-emitting layers may each have a thickness in a range of 20 nm to 50 nm, and may be prepared by ink jet printing, or photolithography, or the like;
(5) preparing an electron transport layer on the quantum dot light-emitting layer: sequentially preparing a red sub-pixel electron transport layer, a green sub-pixel electron transport layer and a blue sub-pixel electron transport layer on the red quantum dot light-emitting layer, the green quantum dot light-emitting layer and the blue quantum dot light-emitting layer by magnetron sputtering, spin coating or the like; wherein the red sub-pixel electron transport layer is a ZnO or ZnMgO nanoparticle thin film, the weight percent content of Mg in ZnMgO is 1% to 5%, the thickness of the red sub-pixel electron transport layer is 40 nm to 300 nm, for example, may be 40 nm to 80 nm, and for example, may also be 60 nm; the green sub-pixel electron transport layer is a ZnO or ZnMgO nanoparticle thin film, the weight percent content of Mg in ZnMgO is 5% to 10%, the thickness of the green sub-pixel electron transport layer is 30 nm to 300 nm, for example, may be 30 nm to 80 nm, and for example, may also be 30 nm, 40 nm, 50 nm, or 80 nm; the blue sub-pixel electron transport layer is a ZnO or ZnMgO nanoparticle thin film, the weight percent content of Mg in ZnMgO is 10% to 20%, the thickness of the blue sub-pixel electron transport layer is 20 nm to 300 nm, for example, the thickness is 20 nm to 40 nm or 40 nm to 80 nm; and
(6) preparing a second electrode (a cathode) on the electron transport layer: wherein the second electrode may be metal Al, Ag, etc., or an IZO film may be deposited by magnetron sputtering, and its thickness may be 10 nm to 100 nm.

Although the implementations of the present disclosure are disclosed above, the contents are only implementations adopted to easily understand the present disclosure and not intended to limit the present disclosure. Any skilled person in the art to which the present disclosure pertains may make any modifications and alterations in forms and details of implementation without departing from the spirit and scope of the present disclosure. However, the patent protection scope of the present disclosure should be subject to the scope defined by the appended claims.

1. A quantum dot light-emitting device, comprising:
a quantum dot light-emitting layer;
a carrier transport layer, located on at least one side of the quantum dot light-emitting layer; and
a monomolecular layer, located between the carrier transport layer and the quantum dot light-emitting layer;
wherein a material of the monomolecular layer is configured in such a way that a molecular configuration is converted from a cis-configuration to a trans-configuration under a visible light irradiation condition or a heating condition, and the molecular configuration is converted from the trans-configuration to the cis-configuration under an ultraviolet irradiation condition, and a molecular chain length of the trans-configuration is greater than that of the cis-configuration.

2. The quantum dot light-emitting device according to claim 1, wherein the monomolecular layer is a self-assembled monomolecular layer.

3. The quantum dot light-emitting device according to claim 2, wherein the material of the monomolecular layer contains at least one of an azo group and 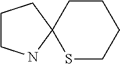
group.

4. The quantum dot light-emitting device according to claim 3, wherein a general structural formula of the material of the monomolecular layer is: 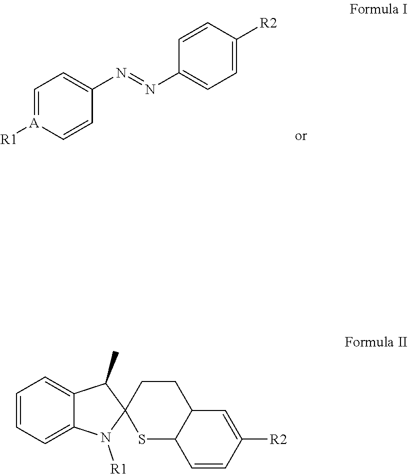
wherein, A in Formula I is a carbon atom or an ammonium ion, and when A in Formula I is an ammonium ion, Formula I further comprises a halogen anion which is selected from at least one of F⁻, Cl⁻, Br⁻ and I⁻; and R1 and R2 in Formula I and Formula II are each independently selected from at least one of alkyl group, —NH₂, amine group, alcoholamine group, —NO₂, —COOH, and a group containing a carbon-carbon double bond.

5. The quantum dot light-emitting device according to claim 4, wherein the material of the monomolecular layer is selected from any one or more of the following compounds:

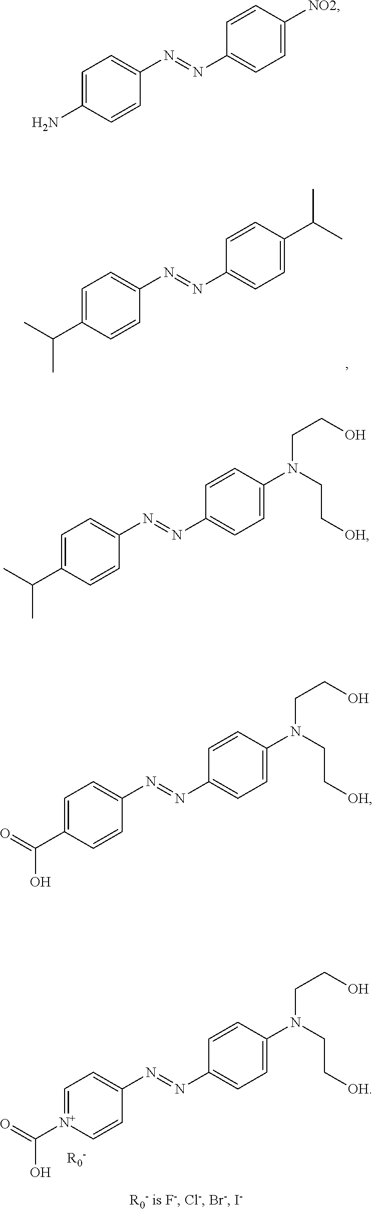

6. The quantum dot light-emitting device according to claim 1, wherein the material of the monomolecular layer is a ligand that is coordinately bound to a quantum dot of the quantum dot light-emitting layer.

7. The quantum dot light-emitting device according to claim 6, wherein the ligand contains at least one of an azo group and 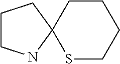
group.

8. The quantum dot light-emitting device according to claim 7, wherein a general structural formula of the ligand is: 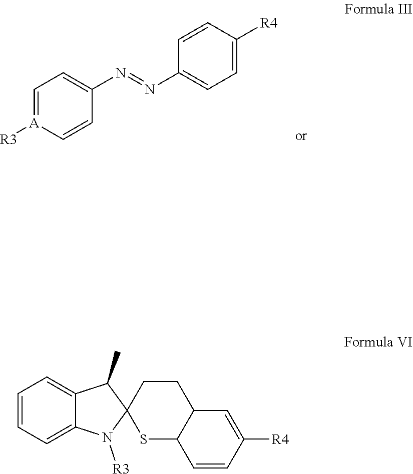
wherein, A in Formula III is a carbon atom or an ammonium ion, and when A in Formula III is an ammonium ion, Formula III further comprises a halogen anion which is selected from at least one of F⁻, Cl⁻, Br⁻ and I⁻; in Formula III and Formula VI, one of R3 and R4 contains a coordination group capable of being coordinately bound to the quantum dot, and the other one of R3 and R4 is a free end, and the coordination group is selected from any one or more of mercapto group, hydroxyl group, amine group, amino group, carboxyl group, ester group, phosphine group and phosphoroxy group.

9. The quantum dot light-emitting device according to claim 8, wherein the ligand is selected from any one or more of: 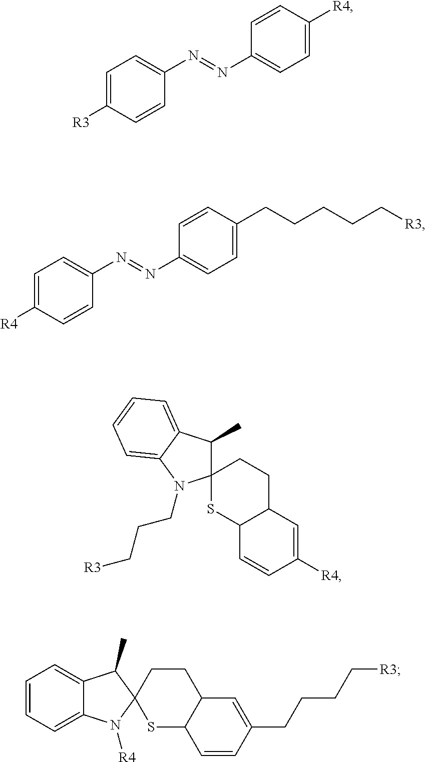
wherein R3 is the coordination group, and R4 is a free end.

10. The quantum dot light-emitting device according to claim 8, wherein the free end contains a siloxane group.

11. The quantum dot light-emitting device according to claim 1, wherein the material of the monomolecular layer is configured such that the molecular configuration is converted from a cis-configuration to a trans-configuration under an 80° C.-150° C. heating condition.

12. The quantum dot light-emitting device according to claim 1, wherein the carrier transport layer is an electron transport layer and comprises an inorganic metal oxide nanoparticle thin film or an inorganic metal oxide thin film, wherein the inorganic metal oxide is selected from any one or more of ZnO, TiO₂, SnO₂, and ZrO₂;
wherein ZnO comprises metal-doped ZnO, and metal doped in the metal-doped ZnO is selected from any one or more of Mg, Al, Zr, and Y.

13. The quantum dot light-emitting device according to claim 12, wherein the electron transport layer comprises a red sub-pixel electron transport layer, a green sub-pixel electron transport layer, and a blue sub-pixel electron transport layer;
the red sub-pixel electron transport layer is an inorganic metal oxide nanoparticle thin film or an inorganic metal oxide thin film, wherein the inorganic metal oxide is ZnO or ZnMgO;
the green sub-pixel electron transport layer is an inorganic metal oxide nanoparticle thin film or an inorganic metal oxide thin film, wherein the inorganic metal oxide is ZnO or ZnMgO;
the blue sub-pixel electron transport layer is an inorganic metal oxide nanoparticle thin film or an inorganic metal oxide thin film, wherein the inorganic metal oxide is ZnO or ZnMgO.

14. The quantum dot light-emitting device according to claim 13, wherein the red sub-pixel electron transport layer, the green sub-pixel electron transport layer, and the blue sub-pixel electron transport layer are ZnMgO nanoparticle thin films or ZnMgO thin films, a weight percent content of Mg in ZnMgO of the red sub-pixel electron transport layer is less than a weight percent content of Mg in ZnMgO of the green sub-pixel electron transport layer, and the weight percent content of Mg in ZnMgO of the green sub-pixel electron transport layer is less than a weight percent content of Mg in ZnMgO of the blue sub-pixel electron transport layer.

15. The quantum dot light-emitting device according to claim 1, wherein the carrier transport layer is a hole transport layer, and a material of the hole transport layer is selected from any one or more of an organic hole transport material and an inorganic metal oxide hole transport material;
the organic hole transport material comprises any one or more of poly(9,9-dioctylfluorene-CO—N-(4-butylphenyl)diphenylamine), polyvinylcarbazole, N,N′-bis(3-methylphenyl)-N,N′-diphenyl-1,1′-biphenyl-4,4′-diamine, and 4,4′-bis(9-carbazolyl)biphenyl;
the inorganic metal oxide hole transport material comprises any one or more of NiO, NiO₂, and V₂O₅.

16. The quantum dot light-emitting device according to claim 15, wherein the hole transport layer comprises a first hole transport layer close to the quantum dot light-emitting layer and a second hole transport layer away from the quantum dot light-emitting layer, a material of the first hole transport layer is a first hole transport material, and a material of the second hole transport layer is a second hole transport material;
$$- 6.2 eV ⩽ \vert HOMO ( A ) \vert ⩽ - 5.5 eV ; - 5.5 eV ⩽ \vert HOMO ( B ) \vert ⩽ - 5. eV$$
wherein HOMO (A) is the highest occupied molecular orbital HOMO energy level of the first hole transport material, and HOMO (B) is the highest occupied molecular orbital HOMO energy level of the second hole transport material,
wherein the first hole transport material is selected from any one or both of 4,4′, 4″-tris(carbazol-9-yl)triphenylamine) and 4,4′-cyclohexylbis[N,N-bis(4-methylphenyl) aniline], and the second hole transport material is selected from any one or both of 4,4′-bis [N-(1-naphthyl)-N-phenylamino]biphenyl and 4,4′,4″-tris(N-3-methylphenyl-N-phenylamino) triphenylamine, and
wherein the thickness of the hole transport layer is 20 nm to 60 nm, the thickness of the first hole transport layer is T_{A}, 0 nm<T_{A}≤10 nm, and the thickness of the second hole transport layer is T_{B}, 20 nm≤T_{B}≤60 nm.

17. The quantum dot light-emitting device according to claim 1, wherein the carrier transport layer is located on both sides of the quantum dot light-emitting layer, the carrier transport layer on one side of the quantum dot light-emitting layer is an electron transport layer, and the carrier transport layer on the other side of the quantum dot light-emitting layer is a hole transport layer;
the electron transport layer comprises an inorganic metal oxide nanoparticle thin film or an inorganic metal oxide thin film, wherein the inorganic metal oxide is selected from any one or more of ZnO, TiO₂, SnO₂, and ZrO₂; wherein ZnO comprises metal-doped ZnO, and metal doped in the metal-doped ZnO is selected from any one or more of Mg, Al, Zr, and Y;
the material of the hole transport layer is selected from any one or more of an organic hole transport material and an inorganic metal oxide hole transport material; wherein the organic hole transport material comprises any one or more of poly(9,9-dioctylfluorene-CO—N-(4-butylphenyl)diphenylamine), polyvinylcarbazole, N,N′-bis(3-methylphenyl)-N,N′-diphenyl-1,1′-biphenyl-4,4′-diamine, and 4,4′-bis(9-carbazolyl)biphenyl; and the inorganic metal oxide hole transport material comprises any one or more of NiO, NiO₂, and V₂O₅.

18. The quantum dot light-emitting device according to claim 17, wherein the electron transport layer comprises a red sub-pixel electron transport layer, a green sub-pixel electron transport layer, and a blue sub-pixel electron transport layer;
the red sub-pixel electron transport layer is an inorganic metal oxide nanoparticle thin film or an inorganic metal oxide thin film, wherein the inorganic metal oxide is ZnO or ZnMgO;
the green sub-pixel electron transport layer is an inorganic metal oxide nanoparticle thin film or an inorganic metal oxide thin film, wherein the inorganic metal oxide is ZnO or ZnMgO; and
the blue sub-pixel electron transport layer is an inorganic metal oxide nanoparticle thin film or an inorganic metal oxide thin film, wherein the inorganic metal oxide is ZnO or ZnMgO.

19. The quantum dot light-emitting device according to claim 18, wherein the red sub-pixel electron transport layer, the green sub-pixel electron transport layer, and the blue sub-pixel electron transport layer are ZnMgO nanoparticle thin films or ZnMgO thin films, a weight percent content of Mg in ZnMgO of the red sub-pixel electron transport layer is less than a weight percent content of Mg in ZnMgO of the green sub-pixel electron transport layer, and the weight percent content of Mg in ZnMgO of the green sub-pixel electron transport layer is less than a weight percent content of Mg in ZnMgO of the blue sub-pixel electron transport layer.

20. The quantum dot light-emitting device according to claim 17, wherein the hole transport layer comprises a first hole transport layer close to the quantum dot light-emitting layer and a second hole transport layer away from the quantum dot light-emitting layer, a material of the first hole transport layer is a first hole transport material, and a material of the second hole transport layer is a second hole transport material;
$$- 6.2 eV ⩽ \vert HOMO ( A ) \vert ⩽ - 5.5 eV ; - 5.5 eV ⩽ \vert HOMO ( B ) \vert ⩽ - 5. eV$$
wherein HOMO (A) is the highest occupied molecular orbital HOMO energy level of the first hole transport material, and HOMO (B) is the highest occupied molecular orbital HOMO energy level of the second hole transport material,
wherein the first hole transport material is selected from any one or both of 4,4′, 4″-tris(carbazol-9-yl)triphenylamine) and 4,4′-cyclohexylbis[N,N-bis(4-methylphenyl) aniline], and the second hole transport material is selected from any one or both of 4,4′-bis [N-(1-naphthyl)-N-phenylamino]biphenyl and 4,4′,4″-tris(N-3-methylphenyl-N-phenylamino) triphenylamine, and
wherein the thickness of the hole transport layer is 20 nm to 60 nm, the thickness of the first hole transport layer is T_{A}, 0 nm<T_{A}≤10 nm, and the thickness of the second hole transport layer is T_{B}, 20 nm≤T_{B}≤60 nm.

21-29. (canceled)
